(19) United States
(12) Patent Application Publication
(10) Pub. No.: US 2018/0138107 A1
(43) Pub. Date: May 17, 2018

(54) LEAD FRAME AND ELECTRONIC COMPONENT DEVICE

(71) Applicant: SHINKO ELECTRIC INDUSTRIES CO., LTD., Nagano-shi (JP)

(72) Inventors: Konosuke Kobayashi, Nagano-shi (JP); Koji Ato, Nagano-shi (JP)

(21) Appl. No.: 15/810,261

(22) Filed: Nov. 13, 2017

(30) Foreign Application Priority Data
Nov. 15, 2016 (JP) 2016-222098

(51) Int. Cl. H01L 23/495

(52) U.S. Cl. CPC H01L 23/49503; H01L 23/49575; H01L 23/4952

(57) ABSTRACT

A lead frame includes a terminal portion. The terminal portion includes: a columnar electrode; a first metal plating layer formed on an upper surface of the electrode; and a second metal plating layer formed on a lower surface of the electrode. The terminal portion includes a plurality of terminal portions. The lead frame further includes a coupling portion that is coupled to the plurality of terminal portions. A first distance between the upper surface of the electrode and the coupling portion is larger than a second distance between the lower surface of the electrode and the coupling portion.

This application claims priority from Japanese Patent Application No. 2016-222098, filed on Nov. 15, 2016, the entire contents of which are herein incorporated by reference.

### BACKGROUND

### 1. Technical Field

The present disclosure relates to a lead frame and an electronic component device.

### 2. Background Art

In the background art, there are lead frames for mounting electronic components such as semiconductor chips. In such a lead frame, a semiconductor chip mounted on a die pad portion is connected to ambient leads through wires, and the semiconductor chip and the wires are sealed with a sealing resin (see e.g., JP-A-2011-29335).

As will be described in paragraphs about an undermentioned preliminary matter, a manufacturing method for an electronic component device using a lead frame has a step of wet-etching a copper plate from a lower surface side thereof to thereby separate a die pad portion and a plurality of terminal portions individually (FIGS. 3B and 3C).

On this occasion, an etching amount of the copper plate is relatively large. Accordingly, a processing time of the etching becomes long to cause a problem of poor production efficiency.

In addition, since the etching amount of the copper plate is relatively large, some condition of an etching solution leads to excessive etching or insufficient etching. Therefore, satisfactory reliability cannot be obtained.

### SUMMARY

According to one or more aspects of the present disclosure, there is provided a lead frame. The lead frame comprises a terminal portion.

The terminal portion comprises:

a columnar electrode;

a first metal plating layer formed on an upper surface of the electrode; and

a second metal plating layer formed on a lower surface of the electrode.

According to one or more aspects of the present disclosure, there is provided an electronic component device.

The electronic component device comprises:

a lead frame comprising a terminal portion, the terminal portion comprising:
a columnar electrode comprising an upper surface, a lower surface, a side surface between the upper surface and the lower surface, and a protrusion formed on the side surface;
a first metal plating layer formed on the upper surface of the electrode; and
a second metal plating layer formed on the lower surface of the electrode,

an electronic component that is mounted on the lead frame to be electrically connected to the terminal portion;

a sealing resin that seals a portion of the lead frame and the electronic component,

wherein the first metal plating layer and a portion of the side surface of the electrode are embedded in the sealing resin, and the second metal plating layer and another portion of the side surface of the electrode are exposed from the sealing resin.

### BRIEF DESCRIPTION OF DRAWINGS

FIGS. 1A to 1C are sectional views (Part 1) showing a manufacturing method for an electronic component device using a lead frame according to a preliminary matter;

FIGS. 2A to 2C are sectional views (Part 2) showing the manufacturing method for the electronic component device using the lead frame according to the preliminary matter;

FIGS. 3A to 3C are sectional views (Part 3) showing the manufacturing method for the electronic component device using the lead frame according to the preliminary matter;

FIG. 4 is a partial sectional view showing a state in which a metal plate is wet-etched using a first metal plating layer as a mask after a step of FIG. 2C;

FIGS. 5A and 5B are sectional views (Part 1) showing a manufacturing method for a lead frame according to a first embodiment;

FIGS. 6A and 6B are a sectional view and a plan view (Part 2) showing the manufacturing method for the lead frame according to the first embodiment;

FIGS. 7A and 7B are sectional views (Part 3) showing the manufacturing method for the lead frame according to the first embodiment;

FIGS. 8A and 8B are a sectional view and a plan view (Part 4) showing the manufacturing method for the lead frame according to the first embodiment;

FIG. 9 is a partial sectional view showing a state in which the bottom of a third recess is formed into a roughened surface in a step of FIGS. 7A and 7B;

FIGS. 10A and 10B are sectional views (Part 5) showing the manufacturing method for the lead frame according to the first embodiment;

FIG. 11 is a sectional view (Part 6) showing the manufacturing method for the lead frame according to the first embodiment;

FIG. 12 is a sectional view showing the lead frame according to the first embodiment;

FIGS. 13A and 13B are a sectional view and a partial plan view (Part 1) showing a manufacturing method for an electronic component device according to the first embodiment;

FIGS. 14A and 14B are sectional views (Part 2) showing the manufacturing method for the electronic component device according to the first embodiment;

FIG. 15 is a sectional view (Part 3) showing the manufacturing method for the electronic component device according to the first embodiment;

FIG. 16 is a sectional view showing the electronic component device according to the first embodiment;

FIGS. 17A and 17B are a sectional view and a plan view (Part 1) showing a manufacturing method for a lead frame according to a second embodiment;

FIG. 18 is a sectional view and a plan view (Part 2) showing the manufacturing method for the lead frame according to the second embodiment;

FIG. 19 is a sectional view showing an electronic component device according to the second embodiment;

FIGS. 20A and 20B are sectional views (Part 1) showing a manufacturing method for a lead frame according to a third embodiment;

FIG. 21 is a sectional view and a plan view showing the lead frame device according to the third embodiment;

FIG. 22 is a sectional view showing an electronic component device according to the third embodiment;

FIGS. 23A and 23B are a sectional view and a plan view (Part 1) showing a manufacturing method for a lead frame according to a fourth embodiment;

FIGS. 24A and 24B are a sectional view and a plan view (Part 2) showing the manufacturing method for the lead frame according to the fourth embodiment;

FIG. 25 is a sectional view showing the lead frame according to the fourth embodiment;

FIG. 26 is a sectional view showing a manufacturing method for an electronic component device according to the fourth embodiment;

FIG. 27 is a sectional view showing the electronic component device according to the fourth embodiment;

FIG. 28 is a sectional view showing a lead frame according to a fifth embodiment;

FIG. 29 is a sectional view showing a manufacturing method for an electronic component device according to the fifth embodiment;

FIG. 30 is a sectional view showing the electronic component device according to the fifth embodiment;

FIG. 31 is a sectional view showing a lead frame according to a sixth embodiment;

FIG. 32 is a sectional view showing a manufacturing method for an electronic component device according to the sixth embodiment; and

FIG. 33 is a sectional view showing the electronic component device according to the sixth embodiment.

### DETAILED DESCRIPTION

Embodiments will be described below with reference to the accompanying drawings.

A preliminary matter underlying the embodiments will be described prior to description of the embodiments.

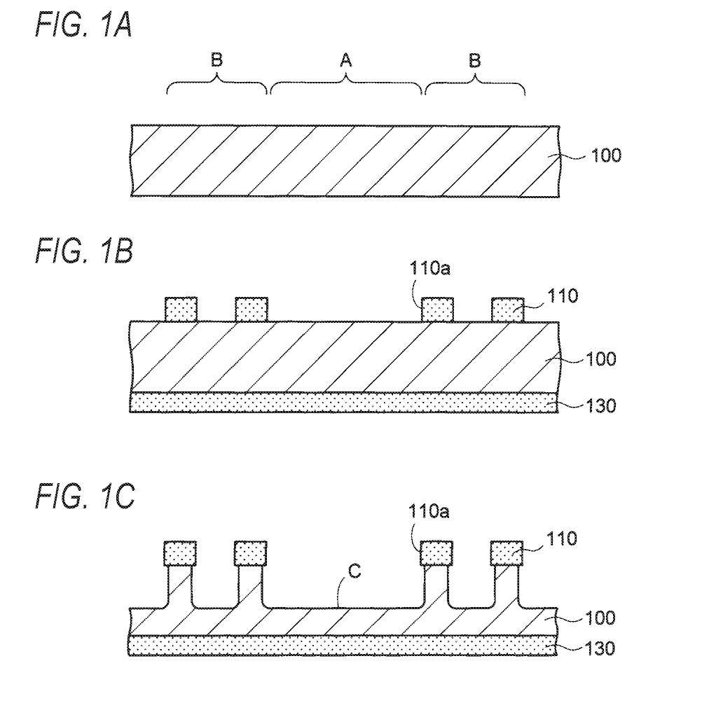

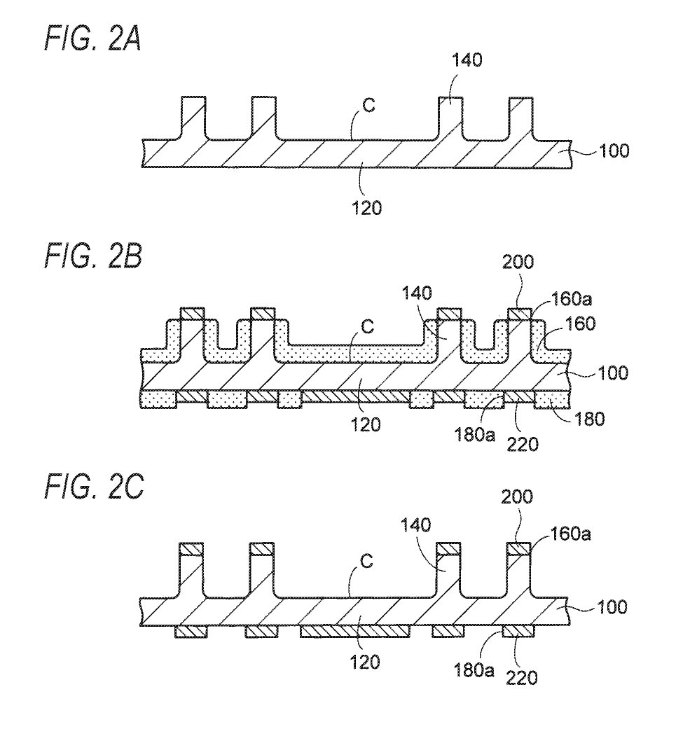

FIGS. 1A to 1C and FIGS. 2A to 2C are views for explaining a lead frame according to the preliminary matter. Description of the preliminary matter is about the details of personal study of the present inventor, which contain techniques not belonging to known techniques.

In a manufacturing method for the lead frame according to the preliminary matter, first, a copper plate 100 is prepared, as shown in FIG. 1A. A die pad formation region A and terminal formation regions B surrounding the die pad formation region A are defined in the copper plate 100.

Next, a first resist layer 110 provided with an opening portion 110a is formed on an upper surface of the copper plate 100, as shown in FIG. 1B. Further, a second resist layer 130 is formed all over a lower surface of the copper plate 100 to thereby protect the lower surface.

The die pad formation region A of the copper plate 100 is disposed inside the opening portion 110a, of the first resist layer 110. In each of the terminal formation regions B of the copper plate 100, patterns of the first resist layer 110 are disposed like islands on portions where terminal portions will be disposed.

Successively, the copper plate 100 is wet-etched to the middle of its thickness through the opening portion 110a of the first resist layer 110 to thereby form a recess C, as shown in FIG. 1C. When, for example, the thickness of the copper plater 100 is about 120 μm, the depth of the recess C is set at about 90 μm.

Then, the first resist layer 110 and the second resist layer 130 are removed, as shown in FIG. 2A.

The recess C is formed on the upper surface side of the copper plate 100. Thus, the recess C is formed in a state in which a die pad portion 120 is connected to the terminal portions 140 disposed around the die pad portion 120.

Next, a first plating resist layer 160 having opening portions 160a provided at upper surfaces of the terminal portions 140 is formed on the upper side of the copper plate 100, as shown in FIG. 2a In addition, a second plating resist layer 180 having opening portions 180a provided at portions which will serve as lower surfaces of the terminal portions 140 and a portion which will serve as a lower surface of the die pad portion 120 is formed on the lower side of the copper plate 100.

As shown in FIG. 2B, a first metal plating layer 200 is formed inside the opening portions 160a of the first plating resist layer 160 by electrolytic plating using the copper plate 100 as a power feed path for the plating. Moreover, in the same manner, a second metal plating layer 220 is formed inside the opening portions 180a of the second plating resist layer 180.

The first plating resist layer 160 and the second plating resist layer 180 are removed, as shown in FIG. 2C.

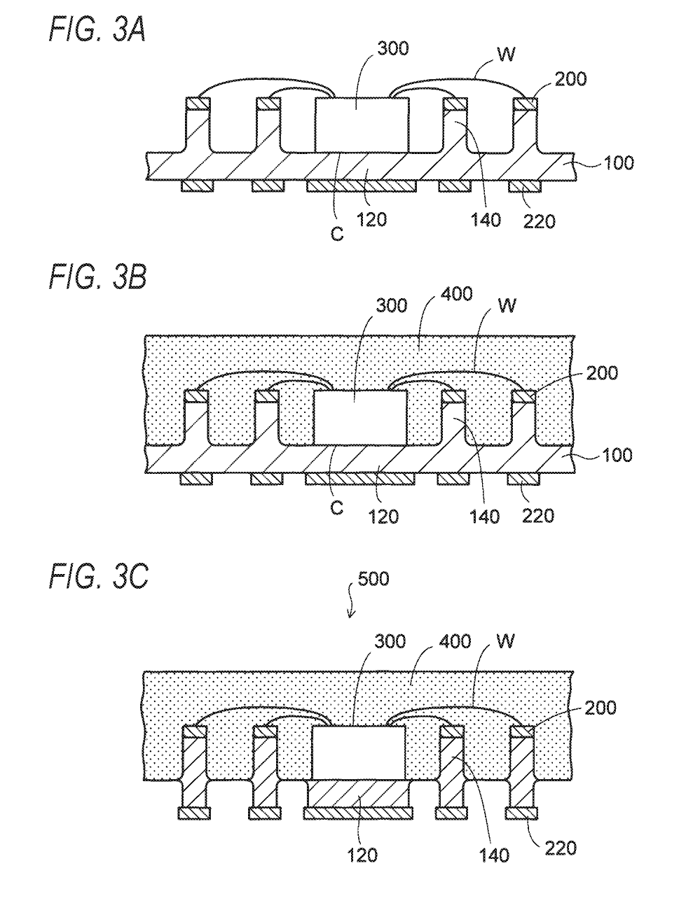

Next, a semiconductor chip 300 is mounted in a face-up disposition on the die pad portion 120 of the copper plate 100, as shown in FIG. 3A. Further, connection terminals of the semiconductor chip 300 are connected to the first metal plating layer 200 on the upper surfaces of the terminal portions 140 of the copper plate 100 through wires W.

Successively, a sealing resin 400 is formed to seal the copper plate 100, the semiconductor chip 300, the terminal portions 140 and the wires W, as shown in FIG. 3B.

Then, as shown in FIG. 3C, using the second metal plating layer 220 on the lower surface of the copper plate 100 as a mask, the copper plate 100 is wet-etched from its lower surface. The etching is performed until an etching surface of the copper plate 100 etched from its lower surface communicates with the recess C of the copper plate 100.

Thus, the copper plate 100 is bored and patterned so that the die pad portion 120 and the terminal portions 140 surrounding the die pad portion 120 can be separated individually. The terminal portions 140 formed thus are provided with the first metal plating layer 200 on their upper surfaces, and the second metal plating layer 220 on their lower surfaces.

In the aforementioned manner, an electronic component device 500 is formed such that the semiconductor chip 300 is mounted on the die pad portion 120 and electrically connected to the terminal portions 140 through the wires W.

When the thickness of the copper plate 100 is 120 μm and the depth of the recess C is 90 μm as described above, an etching amount of the copper plate 100 in the step of FIG. 3C is 30 μm. Thus, the etching amount of the copper plate 100 from the lower surface thereof in the step of FIG. 3C is relatively large. Therefore, a processing time of the etching becomes long to cause a problem of poor production efficiency.

When the recess C is made deeper, the etching amount of the copper plate 100 from the lower surface thereof in the step of FIG. 3C can be reduced. However, when a distance between adjacent ones of the terminal portions 140 is narrow, a recess between the adjacent terminal portions 140 becomes too wide to secure a sufficient area in each of the upper surfaces of the terminal portions 140.

In addition, when there is a fluctuation in process conditions such as the concentration of an etching solution, temperature, etc. for wet-etching the copper plate 100 in the step of FIG. 3C, the etching amount becomes excessive or insufficient. When the etching amount becomes excessive, the etching solution intrudes between the sealing resin 400 and each of side surfaces of the terminal portions 140 to generate a gap therebetween, thereby causing deterioration of sealing property or deterioration of reliability.

On the contrary, when the etching amount becomes insufficient, the terminal portions 140 remain connected to one another to thereby make the product defective.

In addition, it is preferable to increase a height of each of the terminal portions 140 sealed with the sealing resin 400 in the electronic component device 500 in FIG. 3C. This is to increase a region of the terminal portion 140 sealed with the sealing resin 400 to prevent the terminal portion 140 from being detached from the sealing resin 400, to thereby improve reliability.

Alternatively, this is to set both an upper surface of the thick semiconductor chip 300 and the upper surface of the terminal portion 140 at the same height position to thereby shorten a connection distance between the semiconductor chip 300 and the terminal portion 140.

In this case, the following method can be used. That is, after the first metal plating layer 200 is formed on the upper surface of an electrode of the terminal portion 140 in the aforementioned FIG. 2C, the copper plate 100 is further wet-etched with the first metal plating layer 200 as a mask to thereby increase the depth of the terminal portion 140.

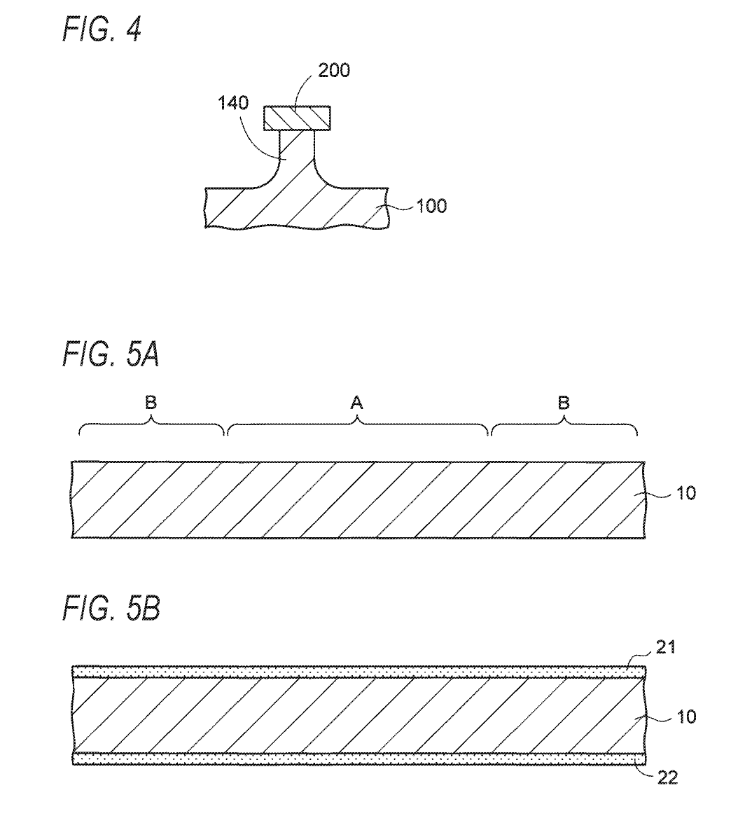

By such a method, the following structure can be formed, as shown in FIG. 4. That is, the electrode of the terminal portion 140 is formed into a shape undercut inward from an end portion of the first metal plating layer 200, and a circumferential edge portion of the first metal plating layer 200 protrudes from the electrode of the terminal portion 140.

Therefore, the first metal plating layer 200 may be detached or chipped easily in a subsequent manufacturing step to thereby cause a problem when wire bonding is performed. In addition, when the first metal plating layer 200 is detached, electric short-circuiting may occur between the terminal portions 140 to thereby cause a decrease in yield.

The aforementioned problem can be solved by any of lead frames according to the embodiments which will be described below.

### First Embodiment

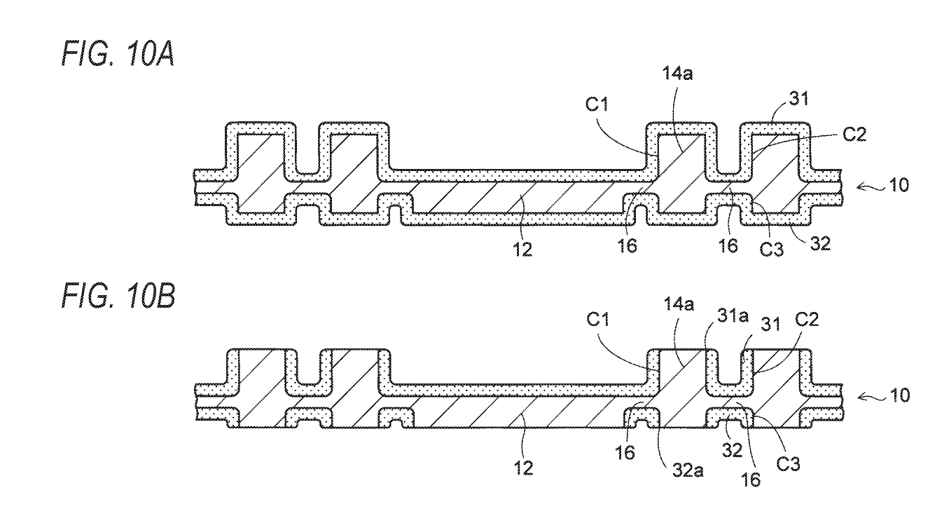

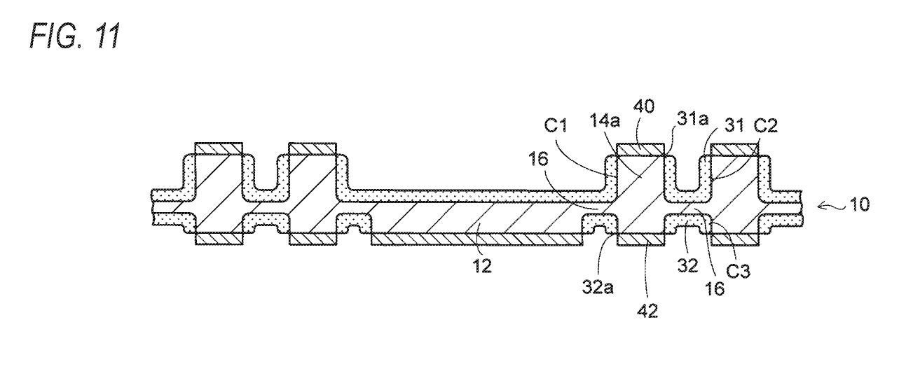

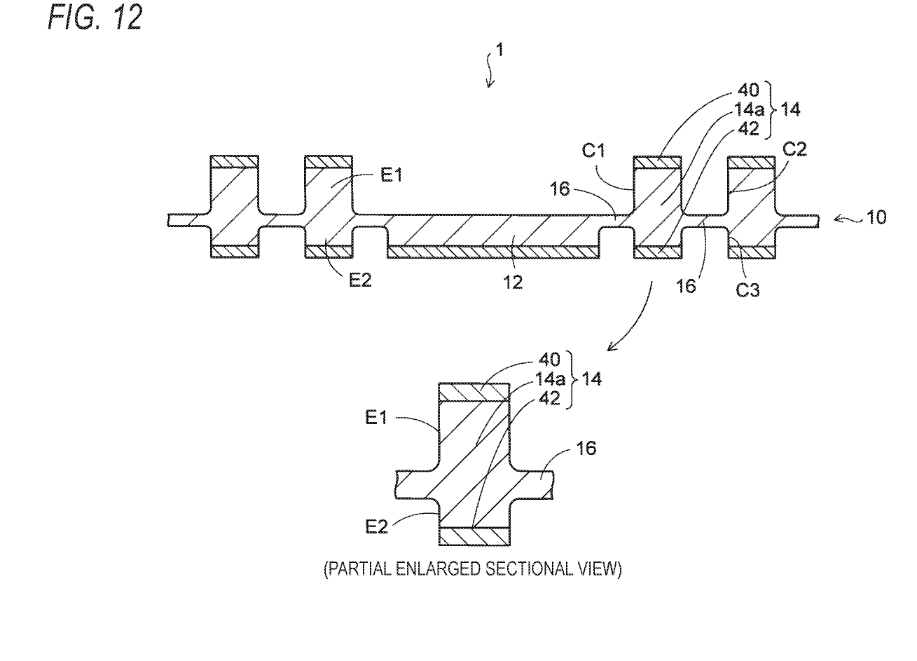

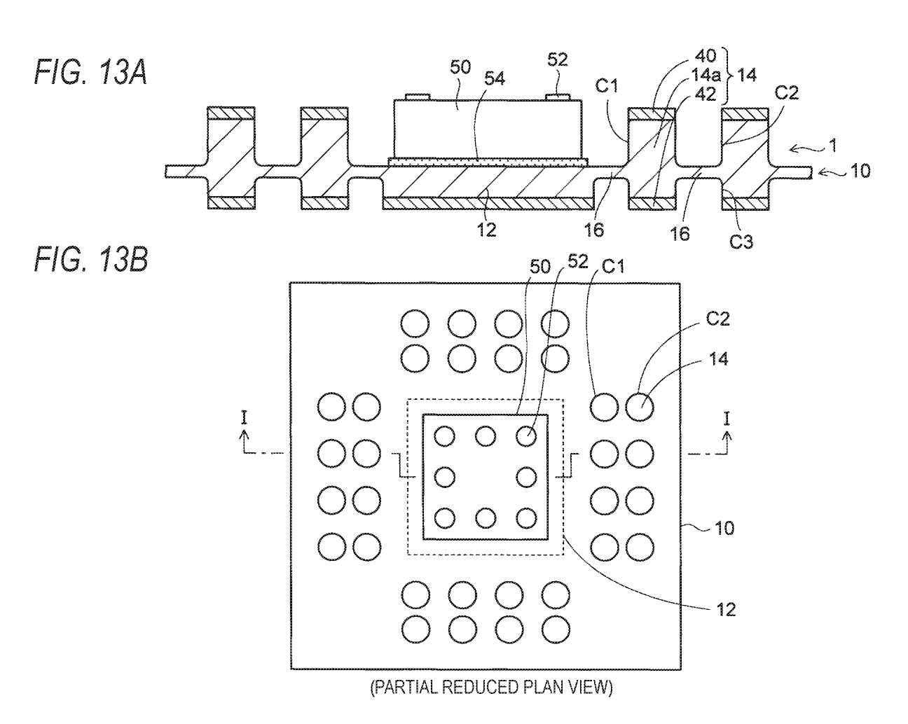

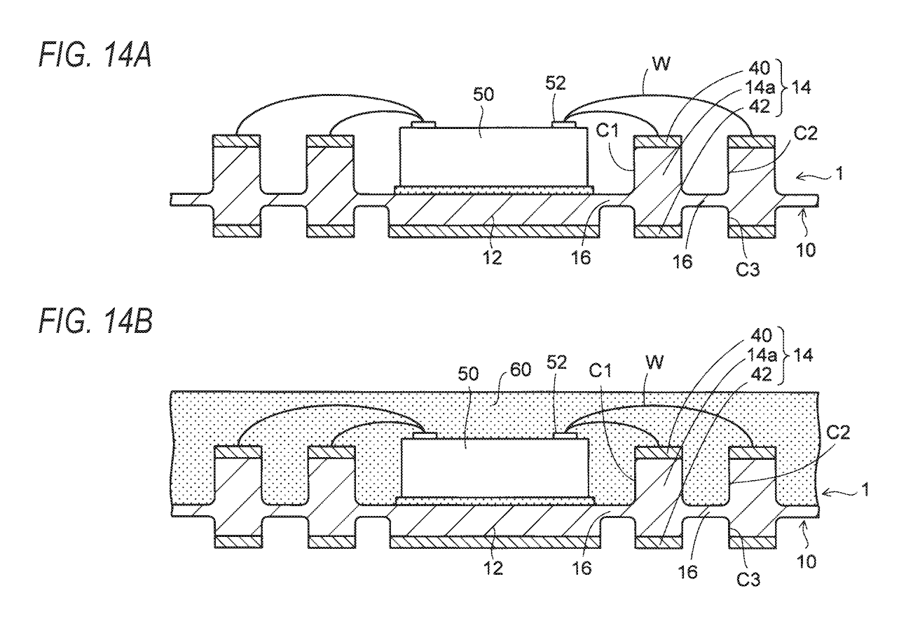

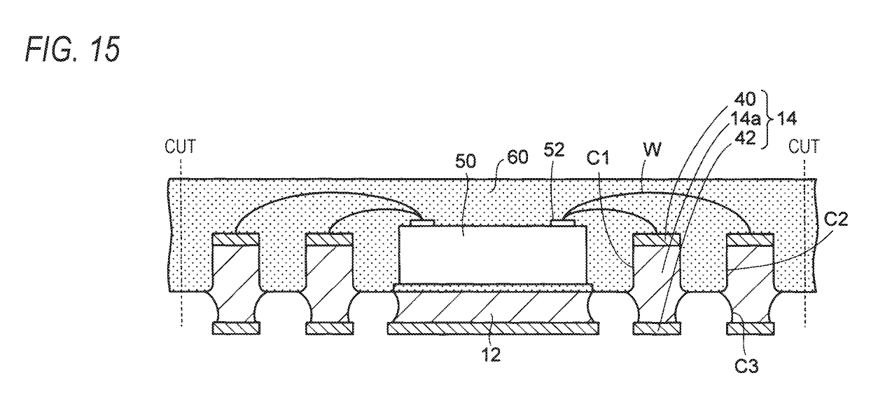

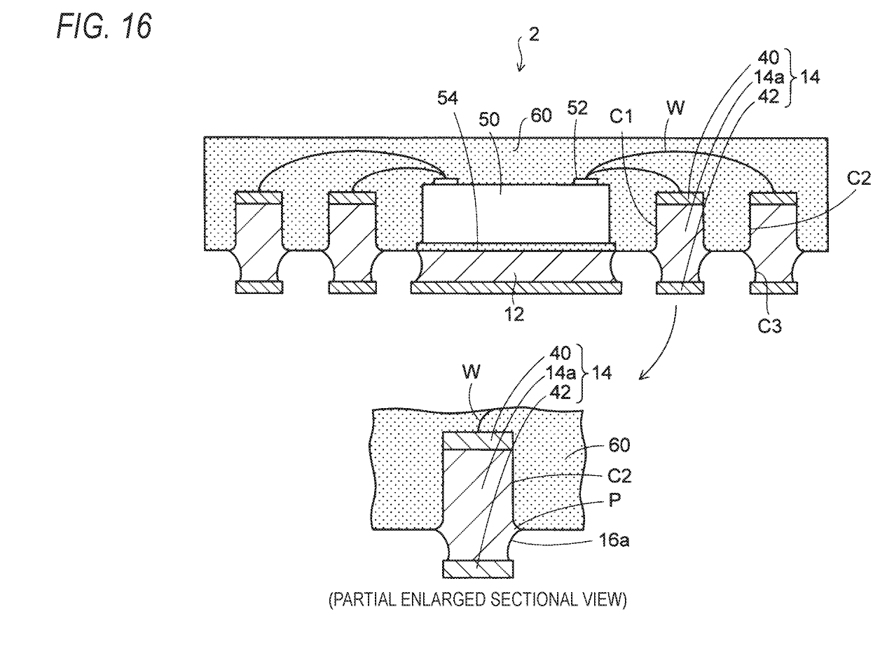

FIGS. 5A and 5B, FIGS. 6A and 6B, FIGS. 7A and 7B, FIGS. 8A and 8B, FIG. FIGS. 10A and 10B and FIG. 11 are views for explaining a manufacturing method for a lead frame according to a first embodiment. FIG. 12 is a view showing the lead frame according to the first embodiment. FIGS. 13A and 13B, 14A and 14B. FIG. 15 and FIG. 16 are views for explaining an electronic component device according to the first embodiment.

The structure of the lead frame and the structure of the electronic component device will be described below while the manufacturing method for the lead frame and the electronic component device is described.

In the manufacturing method for the lead frame according to the first embodiment, first, a metal plate 10 is prepared, as shown in FIG. 5A.

As an example of the metal plate 10, a copper plate made of a copper alloy can be used. Alternatively, various metal plates of 42 Alloy (42% nickel (Ni)-iron (Fe)) etc. can be used as long as they can be used as lead frames. A thickness of the metal plate 10 is, for example, about 120 μm.

A die pad formation region A and terminal formation regions B surrounding the die pad formation region A are defined in the metal plate 10. One metal plate 10 from which lead frames can be obtained contains a plurality of product regions provided in a lattice pattern. The die pad formation region A and the terminal formation regions B are provided in each of the product regions.

Next, a first resist layer 21 is formed on an upper surface of the metal plate 10 and a second resist layer 22 is formed on a lower surface of the metal plate 10, as shown in FIG. 513. A dry film resist or a liquid resist is used as each of the first resist layer 21 and the second resist layer 22.

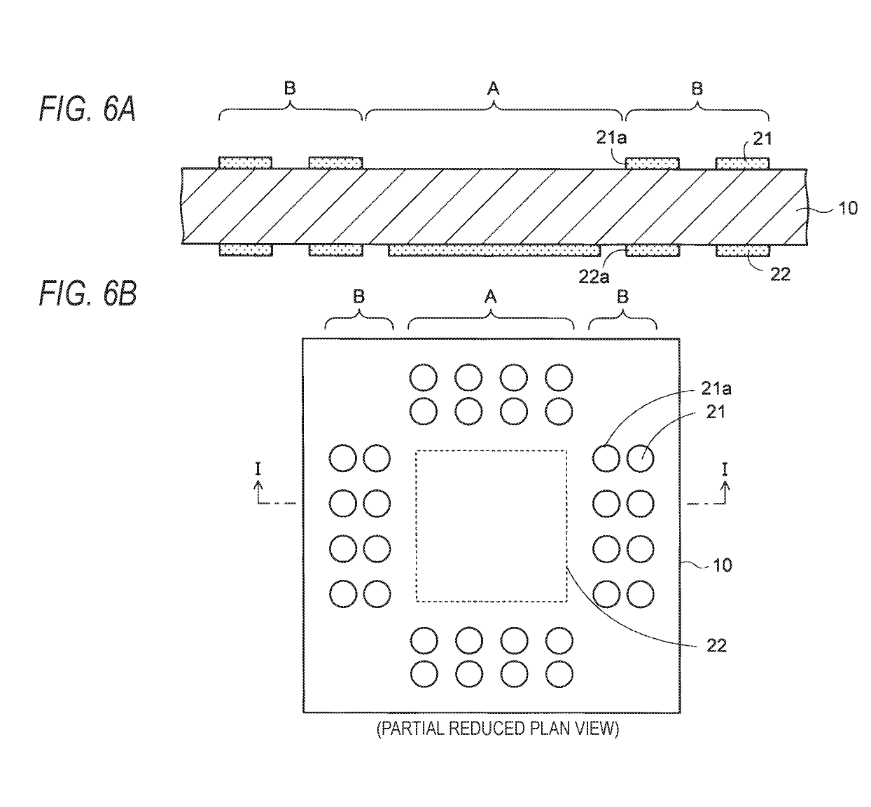

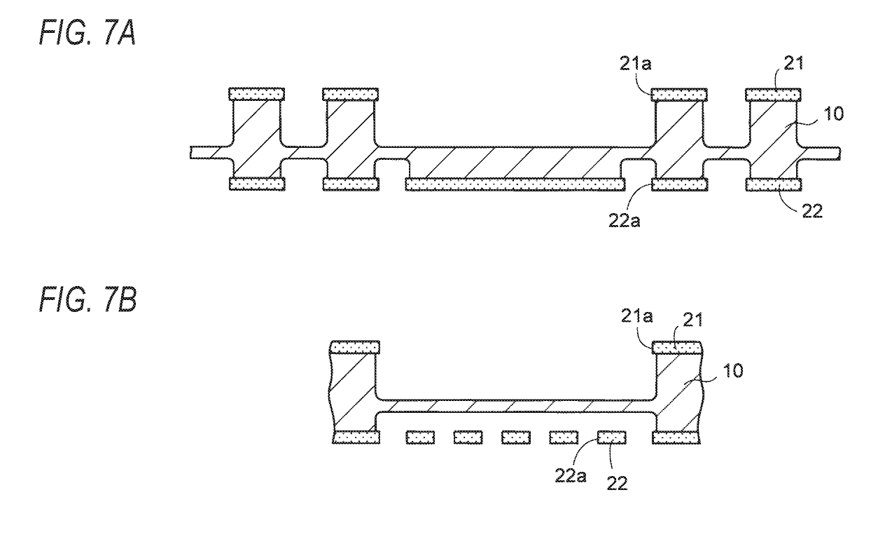

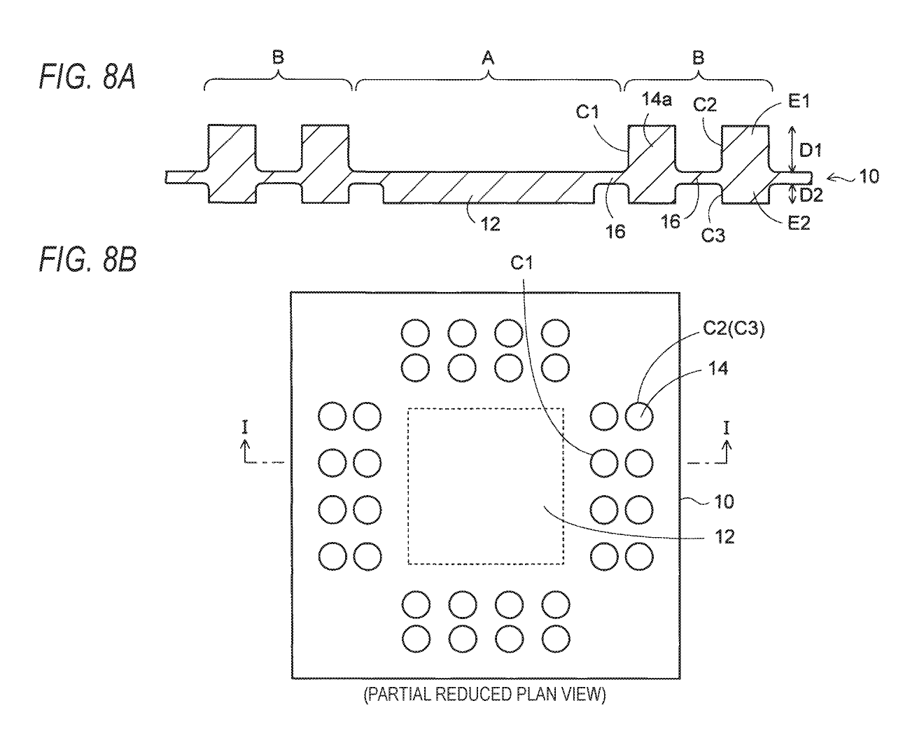

Further, the first resist layer 21 on the upper surface of the metal plate 10 is exposed to light and developed based on photolithography. Thus, the first resist layer 21 is patterned so that an opening portion 21a can be formed, as shown in FIG. 6A.

FIG. 6B is a partial reduced plan view of FIG. 6A. A sectional view of FIG. 6A corresponds to a section taken along a line I-I of the plan view of FIG. 6B. The same rule is also applied to other drawings.

Refer to the partial reduced plan view of FIG. 613 additionally. The first resist layer 21 is patterned like islands disposed on portions of the terminal formation regions F3 of the metal plate 10, which will serve as terminal portions respectively. The die pad formation region A of the metal plate 10 is collectively exposed in the opening portion 21a of the first resist layer 21.

In addition, in the same manner, the second resist layer 22 on the lower surface of the metal plate 10 is exposed to light and developed based on photolithography. Thus, the second resist layer 22 is patterned so that an opening portion 22a can be formed, as shown in FIG. 6A.

The patterns of the second resist layer 22 are collectively disposed on the die pad formation region A of the metal plate 10 and disposed like islands on portions of the terminal formation regions 13, which will serve as the terminal portions respectively.

In each of the terminal formation regions B, the patterns of the first resist layer 21 and the patterns of the second resist layer 22 are disposed in positions corresponding to each other respectively.

Successively, the metal plate 10 is wet-etched to the middle of its thickness from opposite sides through the opening portion 21a of the first resist layer 21 and the opening portion 22a of the second resist layer 22 on the opposite surface sides of the metal plate 10, as shown in FIG. 7A.

When the copper plate is used as the metal plate 10, a ferric chloride solution, a cupric chloride solution, or the like can be used as an etching solution. A spray etching device is preferably used as an etching device.

On this occasion, a depth with which the metal plate 10 has to be etched from its upper surface is set to be larger than a depth with which the metal plate 10 has to be etched from its lower surface. In order to perform such etching, the collective opening portion 21a of the first resist layer 21 is disposed in an etching region on the upper surface side of the metal plate 10, as shown in a schematic view of FIG. 7B. FIG. 7B is a partial enlarged view of the metal plate 10 shown in FIG. 7A.

On the other hand, the opening portion 22a of the second resist layer 22 is divided into lattice-shaped opening portions and disposed in the etching region on the lower surface side of the metal plate 10 so that an opening ratio in the etching region can be reduced.

For example, each of the lattice-shaped opening portions 22a of the second resist layer 22 measures 20 μm by 20 μm to 50 μm by 50 μm. The shape or disposed position of the opening portion 22a of the second resist layer 22 can be set desirably. The opening portions 22a of the second resist layer 22 may be separately disposed in the etching region of the lower surface of the metal plate 10 to thereby set the opening ratio at a predetermined value.

Thus, on the upper surface side of the metal plate 10, the supply of the etchant is increased and an etching rate is therefore increased. On the other hand, on the lower surface side of the metal plate 10, the supply of the etchant is decreased and the etching rate is therefore decreased.

When, for example, the opening ratio of the opening portions 22a of the second resist layer 22 to the etching region of the lower surface of the metal plate 10 is set at about 50%, the etching rate on the lower surface side of the metal plate 10 is about half of the etching rate on the upper surface side of the metal plate 10.

Alternatively, conditions such as pressures of the etching solution to be supplied to the upper surface and the lower surface of the metal plate 10 when the opposite surfaces of the metal plate 10 are etched by a spray etching device may be adjusted so that the etching rate on the upper surface side of the metal plate 10 can be made higher.

In this case, for example, the following etching conditions may be used.
Etching Solution: Cupric Chloride Solution
Temperature of Etching Solution: 40° C.
Upper Side Spray Pressure: 0.13 MPa to 0.17 MPa (e.g. 0.15 MPa)
Lower Side Spray Pressure: 0.03 MPa to 0.07 MPa (e.g. 0.05 MPa)
Conveyor Conveying Speed of Metal Plate 10: 1.55 m/minute

In this case, the lattice-shaped opening portions 22a do not have to be provided in the second resist layer 22 on the lower surface side of the metal plate 10 but the collective opening portion 22a of the second resist layer 22 may be formed in the etching region.

Alternatively, when the etching rate on the lower surface side of the metal plate 10 is set to be considerably low, the lattice-shaped opening portions 22a may be provided in the second resist layer 22 and the aforementioned etching conditions of the spray etching device may be used.

FIG. 8A shows a state in which the first resist layer 21 and the second resist layer 22 have been removed from the metal plate 10 shown in FIG. 7A.

As shown in FIG. 8A, in the die pad formation region A in the upper surface of the metal plate 10, the metal plate 10 is etched to the middle of its thickness from its upper surface so that a first recess C1 can be formed. In addition, since the lower surface of the metal plate 10 in the die pad formation region A is protected by the aforementioned second resist layer 22 shown in FIG. 7A, the lower surface of the metal plate 10 in the die pad formation region A is not etched but stays behind.

Thus, a die pad portion 12 made of a bottom plate of the first recess C1 is formed in the metal plate 10.

In addition, in each of the terminal formation regions B in the upper surface of the metal plate 10, the metal plate 10 is etched to the middle of its thickness from its upper surface so that a second recess C2 can be formed.

Moreover, in the terminal formation region B in the lower surface of the metal plate 10, the metal plate 10 is etched to the middle of its thickness from its lower surface so that a third recess C3 can be formed. Refer to a partial reduced plan view of FIG. 8B additionally. The second recess C2 and the third recess C3 are disposed correspondingly in regions overlapping with each other in plan view.

In this manner, the opposite surfaces of the metal plate 10 are patterned by the first recess C1, the second recess C2 and the third recess C3 so that each of the patterns of the die pad portion 12 and a plurality of electrodes 14a can be formed. In the example of FIG. 8B, the plurality of electrodes 14a are formed like circular columns on the opposite surfaces of the metal plate 10.

Each of the electrodes 14a is provided with a first protruding portion E1 and a second protruding portion E2. The first protruding portion E1 protrudes upward from an upper surface of a coupling portion 16 of the metal plate 10. The second protruding portion E2 protrudes downward from a lower surface of the coupling portion 16 of the metal plate 10.

Alternatively, lead wiring portions in which lead-out wirings are connected to the electrodes 14a may be formed.

In addition, the die pad portion 12 is formed into a rectangle in plan view by way of example.

In addition, between the first recess C1 and the second recess C2 on the upper surface side and the third recess C3 on the lower surface side, a thin plate portion of the metal plate 10 is left as the coupling portion 16.

The die pad portion 12 is coupled to the electrodes 14a by the coupling portion 16. In addition, the plurality of electrodes 14a are coupled to one another by the coupling portion 16.

As described above, the columnar electrodes 14a each of which includes the first protruding portion E1 provided in the upper surface of the metal plate 10 and the second protruding portion E2 provided in the lower surface of the metal plate 10 are formed. The die pad portion 12 and the plurality of electrodes 14a are formed such that the die pad portion 12 is coupled to the plurality of electrodes 14a by the coupling portion 16.

When, for example, the thickness of the metal plate 10 is 120 μm, a depth D1 of each of the first recess C1 and the second recess C2 on the upper surface side is set at about 90 μm, and a depth D2 of the third recess C3 on the lower surface side is set at about 10 μm to 20 μm.

Thus, a height of the first protruding portion E1 of each of the electrodes 14a is set to be higher than a height of the second protruding portion E2 of the electrode 14a. In other words, a distance (i.e. the depth D1) between an upper surface of the electrode 14a and the coupling portion 16 is larger than a distance (i.e. the depth D2) between a lower surface of the electrode 14a and the coupling portion 16. Particularly, a ratio (D1/D2) of the distance between the upper surface of the electrode 14a and the coupling portion 16 to the distance between the lower surface of the electrode 14a and the coupling portion 16 is in a range of 4.5 to 9.

In the embodiment as described above, not only are the first recess C1 and the second recess C2 formed from the upper surface side of the metal plate 10, but the third recess C3 is also formed in advance from the lower surface side of the metal plate 10. Thus, as will be described later, an etching amount with which the coupling portion 16 made of the thin plate portion of the metal plate 10 is etched to separate the electrodes 14a individually can be reduced more greatly than that in the structure according to the preliminary matter.

The third recess C3 in the lower surface of the metal plate 10 is formed simultaneously with the first recess C1 and the second recess C2 in the upper surface of the metal plate 10. Therefore, the formation of the third recess C3 does not cause any increase in the number of steps.

When the metal plate 10 is etched from its lower surface side through the lattice-shaped opening portions 22a of the second resist layer 22, as described in the aforementioned FIG. 7B, a large number of fine holes formed in the lower surface of the metal plate 10 finally communicate with one another to thereby form the third recess C3.

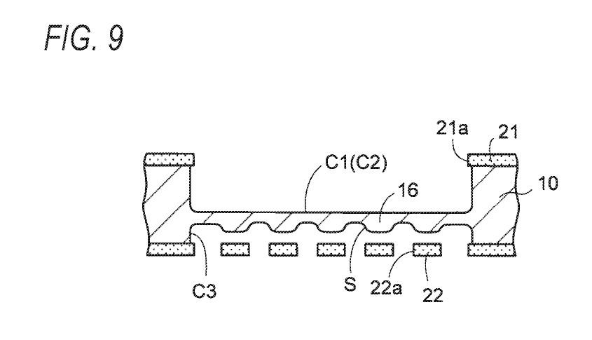

Opening conditions of the opening portions 22a of the second resist layer 22 or etching conditions may be adjusted so that the bottom of the third recess C3 (the lower surface of the coupling portion 16) can be also formed into a roughened surface S where fine irregularities are formed, as shown in FIG. 9.

Thus, surface roughness of the bottom of the third recess C3 (the lower surface of the coupling portion 16) may be set to be larger than surface roughness of each of the bottoms of the first recess C1 and the second recess C2 (each of the upper surface of the coupling portion 16 and an upper surface of the die pad portion 12).

In addition, when the bottom of the third recess C3 (the lower surface of the coupling portion 16) is formed into the roughened surface S, etching speed for etching the coupling portion 16 can be increased due to an increase in surface area of the bottom. Accordingly, productivity can be improved.

Next, as shown in FIG. 10A, a first plating resist layer 31 is formed on an upper surface of a structure body shown in FIG. 8A, and a second plating resist layer 32 is formed on a lower surface of the structure body. Each of the first plating resist layer 31 and the second plating resist layer 32 is formed by an electrodepositing resist.

Alternatively, the metal plate 10 in which the first to third recesses C1 to C3 have been formed may be immersed in a liquid resist so that the resist can be deposited on each of the opposite surfaces of the metal plate 10.

Further, the first plating resist layer 31 on the upper surface of the metal plate 10 is exposed to light and developed based on photolithography, as shown in FIG. 10B. Thus, the first plating resist layer 31 is patterned so that opening portions 31a can be formed. The opening portions 31a of the first plating resist layer 31 are disposed on the upper surfaces of the electrodes 14a to expose the upper surfaces of the electrodes 14a.

Successively, the second plating resist layer 32 on the lower surface of the metal plate 10 is exposed to light and developed based on photolithography. Thus, the second plating resist layer 32 is patterned so that opening portions 32a can be formed.

The opening portions 32a of the second plating resist layer 32 are disposed on the lower surfaces of the electrodes 14a and a lower surface of the die pad portion 12 to expose the lower surfaces of the electrodes 14a and the lower surface of the die pad portion 12.

Next, as shown in FIG. 11, electrolytic plating is performed using the metal plate 10 as a power feed path for the plating. In the metal plate 10, the die pad portion 12 and the electrodes 14a have been formed. Thus, a first metal plating layer 40 is formed on the upper surfaces of the electrodes 14a inside the opening portions 31a of the first plating resist layer 31.

In addition, a second metal plating layer 42 is formed on the lower surfaces of the electrodes 14a and the lower surface of the die pad portion 12 inside the opening portions 32a of the second plating resist layer 32.

Thus, each of the terminal portions 14 is configured by the electrode 14a, the first metal plating layer 40 which is formed on the upper surface of the electrode 14a, and the second metal plating layer 42 which is formed on the lower surface of the electrode 14a.

As an example of each of the first metal plating layer 40 and the second metal plating layer 42, a multilayer film including a nickel (Ni) layer/a palladium (Pd) layer/a gold (Au) layer sequentially from the electrode 14a side can be used. For example, the Ni layer is 1.0 μm thick, the Pd layer is 0.05 μm thick, and the Au layer is 0.01 μm to 0.02 μm thick. The gold layer may be a gold (Au)-silver (Ag) alloy layer.

Alternatively, a multilayer film including a nickel (Ni) layer/a gold (Au) layer sequentially from the electrode 14a side may he used.

Further, a silver (Ag) plating layer or a tin (Sn) plating layer may be used as each of the first metal plating layer 40 and the second metal plating layer 42.

Thus, the first metal plating layer 40 and the second metal plating layer 42 are formed to contain noble metal such as gold or silver.

Then, as shown in FIG. 12, the first plating resist layer 31 and the second plating resist layer 32 are removed from a structure body shown in FIG. 11.

In the aforementioned manner, each lead frame 1 according to the first embodiment can be obtained.

As shown in FIG. 12, the lead frame 1 according to the first embodiment is provided with the die pad portion 12, and the terminal portions 14 which are disposed around the die pad portion 12.

In the lead frame 1, the first recess C1 and the second recess C2 are formed on the upper surface side of the metal plate 10, and the third recess C3 is formed on the lower surface side of the metal plate 10. The third recess C3 is disposed in the position corresponding to the second recess C2. In addition, the first recess C1, the second recess C2 and the third recess C3 are formed to extend up to the middle of the thickness of the metal plate 10.

The die pad portion 12 is made of the bottom plate of the first recess C1 of the metal plate 110. The bottom plate of the first recess C1 is the remaining portion of the metal plate 10 which has been etched to the middle of its thickness from its upper surface side. The die pad portion 12 is provided to protrude downward from the lower surface of the coupling portion 16 of the metal plate 10.

Each of the terminal portions 14 is provided with the electrode 14a which is made of the metal plate 10. The electrode 14a of the terminal portion 14 is formed by the first recess C1, the second recess C2 and the third recess C3. The first recess C1 and the second recess C2 are formed on the upper surface side of the metal plate 10. The third recess C3 is formed on the lower surface side of the metal plate 10.

The electrode 14a is provided to protrude from the upper surface and the lower surface of the metal plate 10. The electrode 14a has the first protruding portion E1 provided in the upper surface of the metal plate 10 and the second protruding portion E2 provided in the lower surface of the metal plate 10. Thus, one second protruding portion E2 on the lower surface side is provided on one first protruding portion E1 on the upper surface side correspondingly so that one electrode 14a can be built.

As an example, the electrode 14a is protrusively formed like a column. Examples of the column include a circular column, a square column, etc.

In addition, the electrode 14a may be protrusively formed into a truncated cone in which the diameter of a front end is smaller than the diameter of a base portion (the metal plate 10 side diameter).

Further, a side surface of the protruding electrode 14a may be formed into a curved shape. In this case, the side surface of the electrode 14a is formed into the curved shape curved in an axis direction of the electrode 14a protruding like a column.

In this manner, one terminal portion 14 protruding like the column from the upper surface and the lower surface of the metal plate 10 is provided.

Between the first recess C1 and the third recess C3 and between the second recess C2 and the third recess C3, the thin plate portion of the metal plate 10 is left as the coupling portion 16.

The die pad portion 12 is connected and coupled to the electrodes 14a of the terminal portions 14 by the coupling portion 16. In addition, the electrodes 14a of the terminal portions 14 are connected and coupled to one another by the coupling portion 16.

The electrodes 14a of the terminal portions 14 disposed in an outermost region are connected to an outer frame (not shown) by the coupling portion 16 so as to be supported by the outer frame.

The side surfaces of upper portions of the electrodes 14a of the terminal portions 14, the upper surface of the coupling portion 16, and the upper surface of the die pad portion 12 are exposed from the first metal plating layer 40.

In addition, as shown in a partial enlarged sectional view in FIG. 12, the first metal plating layer 40 is formed on the upper surface of the electrode 14a of each terminal portion 14. In the first embodiment, an area of the first metal plating layer 40 is set to be equal to an area of the upper surface of the electrode 14a, as a first example of a structure in which a circumferential edge portion of a lower surface of the first metal plating layer 40 makes contact with the first protruding portion E1.

A side surface of the first metal plating layer 40 is flush with the side surface of the electrode 14a. The entire side surface of the first protruding portion E1 of the electrode 14a is exposed from the first metal plating layer 40.

In addition, the second metal plating layer 42 is formed on the lower surface of the electrode 14a of each terminal portion 14. An area of the second metal playing layer 42 is set to be equal to an area of the lower surface of the electrode 14a. The entire side surface of the second protruding portion E2 of the electrode 14a is exposed from the second metal plating layer 42.

In addition, the coupling portion 16 is coupled to a side surface upper portion of the die pad portion 12, and a side surface lower portion of the die pad portion 12 is disposed to extend downward from the coupling portion 16. Further, the second metal plating layer 42 is formed on the lower surface of the die pad portion 12. The second metal plating layer 42 is formed separately on the die pad portion 12 and the terminal portion 14. The side surface of the die pad portion 12 is exposed from the second metal plating layer 42.

In the example of FIG. 12, the terminal portions 14 are disposed like islands (FIG. 8B). However, the terminal portions 14 may be used as pads and lead wire portions in which lead-out wirings are connected to the pads may be formed separately from one another.

As will be described later, with the second metal plating layer 42 as a mask, the coupling portion 16 is wet-etched from its lower surface side to be bored. Thus, the die pad portion 12 is separated from the terminal portions 14, and the terminal portions 14 are separated from one another.

In the embodiment, the third recess C3 is also formed in advance in the lower surface of the metal plate 10 simultaneously when the first and second recesses C1 and C2 are formed in the upper surface of the metal plate 10. Thus, a thickness of the coupling portion 16 is reduced.

When, for example, the thickness of the copper plate 100 is 120 μm, the thickness of the coupling portion of the copper plate 100 is 30 μm according to the method described in the preliminary matter.

On the other hand, in the embodiment, the metal plate 10 is etched to a depth of 90 μm from its upper surface side, and etched to a depth of 10 μm to 20 μm from its lower surface side. Thus, the coupling portion 16 of the metal plate 10 is 10 μm to 20 μm (120 μm−(90 μm+(10 μm to 20 μm))) thick. Thus, an etching amount for removing the coupling portion 16 can be reduced.

Accordingly, a processing time of etching the coupling portion 16 is shortened so that production efficiency can be improved. In addition, since the etching time is shortened, a risk of excessive etching or insufficient etching can be reduced even when there is a fluctuation in process conductions such as concentration of the etching solution, temperature. etc.

In addition, in the lead frame 1 according to the embodiment, the height of the first protruding portion E1 of each terminal portion 14 is set to be higher than the height of the second protruding portion E2 of the terminal portion 14. As will be described later, the entire side surface of the first protruding portion E1 of the electrode 14a is sealed with a sealing resin when an electronic component device is built.

When the height of the first protruding portion E1 of the terminal portion 14 is high on this occasion, a region of the terminal portion 14 sealed with the sealing resin is large. Accordingly, the terminal portion 14 can be prevented from being detached from the sealing resin, so that reliability can be improved.

Further, when an electronic component is mounted on the die pad portion 12, it is preferable that an upper surface of the electronic component and the upper surface of the terminal portion 14 are disposed in the same height positions for the reason for minimizing the length of each wire for wiring bonding.

In the lead frame according to the embodiment, the height of the first protruding portion E1 of the terminal portion 14 can be set easily to be higher than the height of the second protruding portion E2 of the terminal portion 14, as having been described in the aforementioned manufacturing method. Therefore, the height of the first protruding portion E1 of the terminal portion 14 can be adjusted to be suited to the thickness of the electronic component even when an electronic component thick in thickness is mounted.

In addition, in the manufacturing method for the lead frame 1 according to the embodiment, it is not necessary to further etch the electrode 14a from the upper surface side after the first metal plating layer 40 is formed on the upper surface of the electrode 14a in the aforementioned FIG. 11.

This is because the etching rate on the upper surface side can be set to be higher than the etching rate on the lower surface side when the opposite surfaces of the metal plate 10 are etched in the aforementioned FIGS. 7A and 7B so that the first protruding portion E1 with a desired length can be formed by etching at one time.

Accordingly, the area of the first metal plating layer 40 is equal to the area of the upper surface of the electrode 14a. The circumferential edge portion of the lower surface of the first metal plating layer 40 makes contact with the electrode 14a. That is, the entire lower surface of the first metal plating layer 40 makes contact with the electrode 14a.

Therefore, detachment of the first metal plating layer 40 or occurrence of pattern chipping can be prevented and a sufficient wire bonding region can be secured. Accordingly, reliability when wiring bonding is performed can be improved.

Next, a method for using the lead frame 1 in FIG. 12 to build the electronic component device will be described.

As shown in FIG. 13A, a semiconductor chip 50 having connection terminals 52 provided on its front surface is prepared. The connection terminals 52 of the semiconductor chip 50 face up and a back surface of the semiconductor chip 50 is fixed on the die pad portion 12 of the lead frame 1 by an adhesive agent 54.

As shown in a partial reduced plan view of FIG. 13B, the semiconductor chip 50 is mounted on the square die pad portion 12 and surrounded by the plurality of terminal portions 14.

The semiconductor chip 50 is an example of the electronic component. Various electronic components may be mounted on the die pad portion 12 of the lead frame 1.

Successively, as shown in FIG. 14A, the connection terminals 52 of the semiconductor chip 50 are connected to the first metal plating layer 40 at upper ends of the terminal portions 14 of the lead frame 1 through the wires W by a wire bonding method. As each of the wires W, a metal wire made of gold, aluminum, copper, or the like, can be used.

Further, a sealing resin (an encapsulation resin) 60 is formed on the lead frame 1 to seal (or to encapsulate) the semiconductor chip 50, the terminal portions 14, and the wires W, as shown in FIG. 14B. As an example of the sealing resin 60, an insulating resin such as an epoxy resin can be used.

On this occasion, the die pad portion 12 and the terminal portions 14 are coupled to each other by the coupling portion 16. Therefore, the sealing resin 60 is not formed on the lower surface side of the lead frame 1 so that the second metal plating layer 42 on the lower sides of the terminal portions 14 can he exposed from the sealing resin 60 as it is.

Next, as shown in FIG. 14B and FIG. 15, with the second metal plating layer 42 in the lower surfaces of the terminal portions 14 as a mask, the coupling portion 16 of the lead frame 1 is wet-etched from the lower surface side. The coupling portion 16 is bored by the wet etching so that a lower surface of the sealing resin 60 can be exposed. Thus, the lower surface of the metal plate 10 is etched with the second metal plating layer 42 as the mask. Accordingly, the metal plate 10 is removed.

Thus, the die pad portion 12 is separated from the terminal portions 14, and the terminal portions 14 are separated individually, as shown in FIG. 15.

The die pad portion 12 and each terminal 14 are integrated with each other by the sealing resin 60. Accordingly, even when the die pad portion 12 and the terminal portion 14 are separated from each other, the both are supported by the sealing resin 60.

On this occasion, the etching tune of the coupling portion 16 of the lead frame 1 is shortened, as described above. Accordingly, production efficiency can be improved. In addition, the risk of excessive etching or insufficient etching can be reduced. Consequently, it is possible to solve a problem that a gap may be generated between the sealing resin 60 and each of the side surfaces of the terminal portions 14 or the terminal portions 14 may remain connected to one another.

Then, the sealing resin 60 and the lead frame 1 are cut in order to obtain each individual product. The product regions disposed in the lattice pattern in the metal plate 10 are divided into individual product regions. Thus, individual electronic component devices can be obtained.

In the case where the metal plate 10 and the coupling portion 16 between adjacent ones of the product regions have been completely removed by etching, only the sealing resin 60 is cut. Thus, individual electronic component devices can be obtained.

In the aforementioned manner, the electronic component devices 2 according to the first embodiment can be obtained, as shown in FIG. 16.

In each of the electronic component devices 2 according to the first embodiment as shown in FIG. 16, the back surface of the semiconductor chip 50 having the connection terminals 52 face up is fixed on the die pad portion 12 by the adhesive agent 54. The die pad portion 12 is made of the metal plate 10.

The plurality of terminal portions 14 are separated like islands and disposed around the die pad portion 12. Each of the terminal portions 14 is formed like a column. A lower end side of the terminal portion 14 is provided to protrude downward from the sealing resin 60.

Refer to a partial enlarged sectional view in FIG. 16 additionally. The terminal portion 14 is formed to include the electrode 14a, the first metal plating layer 40 and the second metal plating layer 42. The first metal plating layer 40 is formed on the upper surface of the electrode 14a. The second metal plating layer 42 is formed on the lower surface of the electrode 14a.

In addition, the connection terminals 52 of the semiconductor chip 50 are connected to the first metal plating layer 40 in the upper surfaces of the terminal portions 14 through the wires W. Moreover, the semiconductor chip 50, the wires W and the upper portions of the terminal portions 14 are sealed with the sealing resin 60.

With the second metal plating layer 42 as a mask, the aforementioned coupling portion 16 of the lead frame 1 in FIG. 12 is wet-etched from the lower surface side. Thus, the terminal portions 14 of the electronic component device 2 are separated from one another.

Refer to the partial enlarged sectional view in FIG. 16. The coupling portion 16 is etched isotropically from pattern end portions of the second metal plating layer 42. Accordingly, an etching surface 16a of the coupling portion 16 is formed into an undercut shape. Therefore, circumferential edge portions of an upper surface of the second metal plating layer 42 are exposed from the electrodes 14a.

In addition, the etching surface 16a of the coupling portion 16 intersects with inner surfaces of the first recess C1 and the second recess C2. Thus, side surface protrusions P protruding outward are formed on the side surfaces of the electrodes 14a of the terminal portions 14. Front ends of the side surface protrusions P are disposed to be positioned on the lower surface of the sealing resin 60.

Thus, each of the electrodes 14a of the terminal portions 14 is provided with the upper surface, the lower surface, the side surface formed between the upper surface and the lower surface and the protrusion P formed on the side surface. The height of the upper portion of the electrode 14a is set to be higher than the height of the lower portion of the electrode 14a. Further, a corresponding one of the circumferential edge portions of the lower surface of the first metal plating layer 40 makes contact with the electrode 14a.

The first metal plating layer 40 and the upper portion of the electrode 14a in the terminal portion 14 are sealed with the sealing resin 60. In addition, the second metal plating layer 42 and the lower portion of the electrode 14a in the terminal portion 14 are exposed from the sealing resin 60. That is, the first metal plating layer 40 and one portion of the side surface of the electrode 14a are embedded in the sealing resin 60, and the second metal plating layer 42 and the other portion of the side surface of the electrode 14a are exposed from the sealing resin 60.

In this manner, the region of the terminal portion 14 sealed with the sealing resin 60 is larger than a region of the terminal portion 14 exposed from the sealing resin 60. Accordingly, reliability of the terminal portion 14 can be improved.

The electronic component device 2 according to the embodiment is manufactured using the aforementioned lead frame 1 shown in FIG. 12. Accordingly, the problem described in the preliminary matter can be solved so that the electronic component device 2 can be manufactured reliably with a high yield.

### Second Embodiment

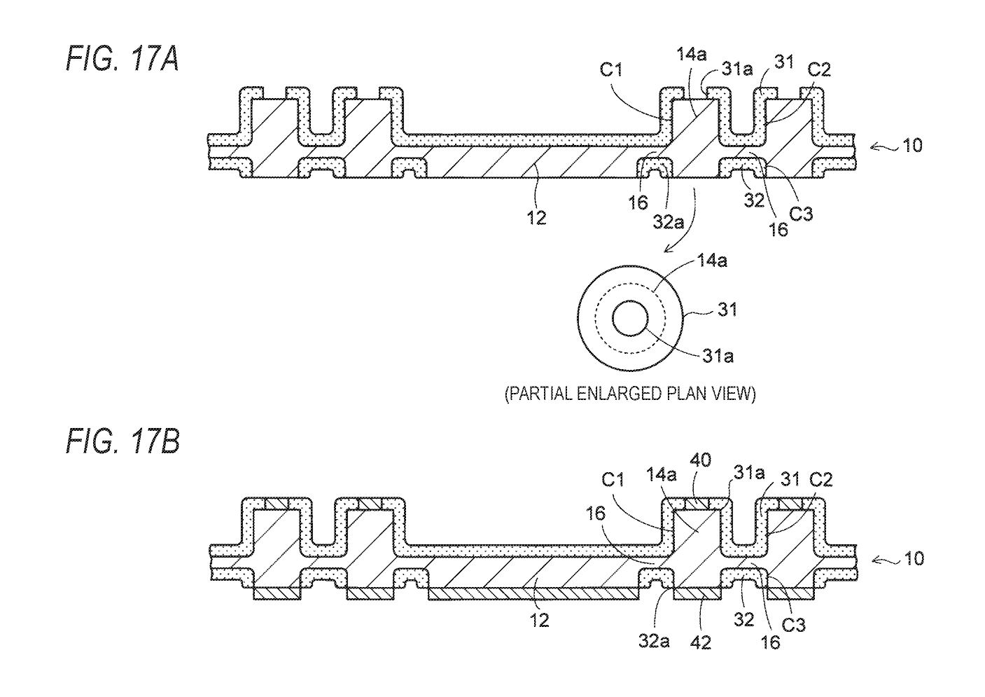

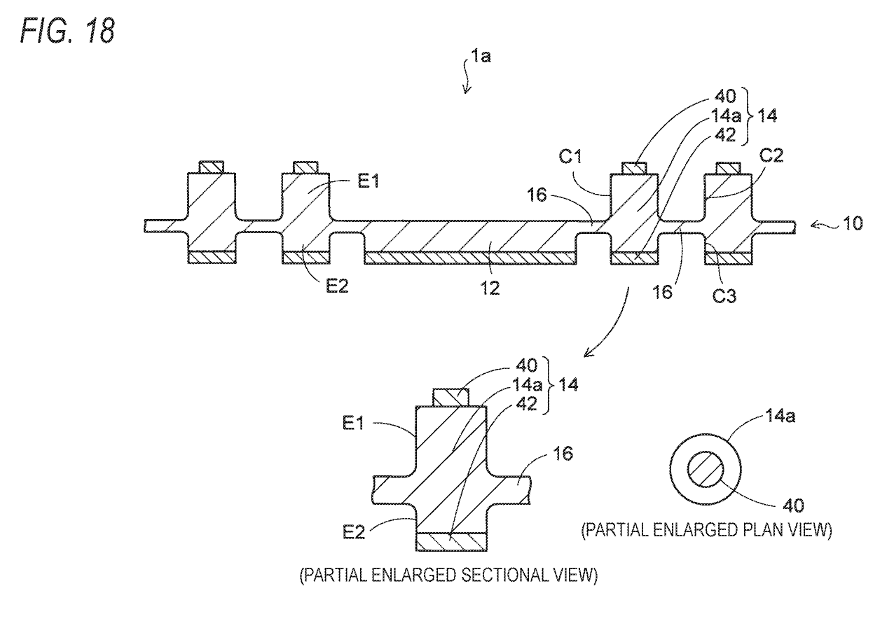

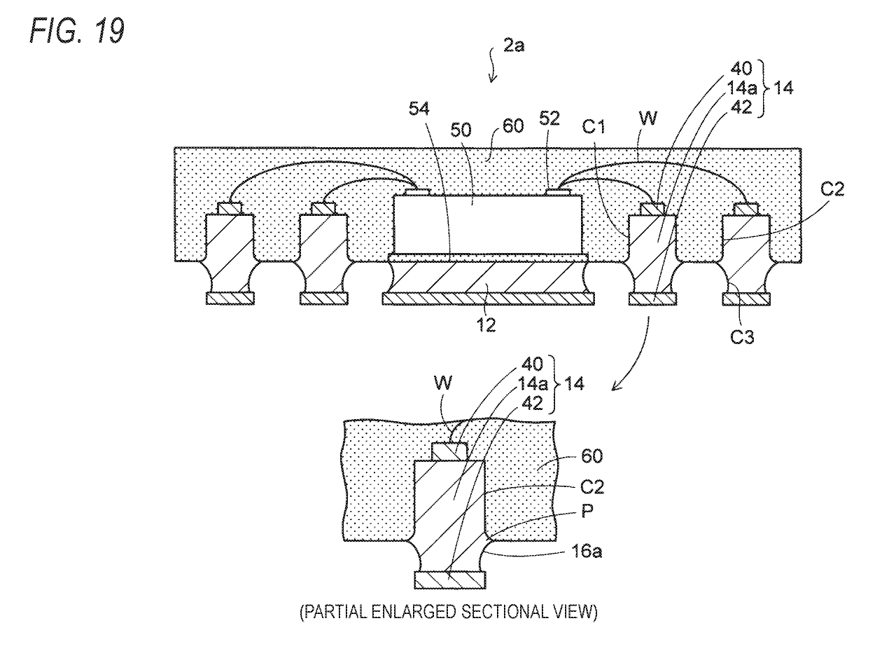

FIGS. 17A and 17B and FIG. 18 are views for explaining a lead frame according to a second embodiment. FIG. 19 is a view showing an electronic component device according to the second embodiment.

In a manufacturing method for the lead frame according to the second embodiment, positions of opening portions 31a of a first plating resist layer 31 in the aforementioned step of FIGS. 10A and 10B are changed, as shown in FIG. 17A.

Refer to a partial enlarged plan view in FIG. 17A additionally. The opening portions 31a of the first plating resist layer 31 are disposed on central portions of upper surfaces of electrodes 14a, and circumferential edge portions of the upper surfaces of the electrodes 14a are covered with the first plating resist layer 31.

Next, as shown in FIG. 17B, a first metal plating layer 40 is formed on the central portions of the upper surfaces of the electrodes 14a inside the opening portions 31a of the first plating resist layer 31 in the same manner as in the aforementioned step of FIG. 11. In addition, a second metal plating layer 42 is formed on lower surfaces of the electrodes 14a inside opening portions 32a of a second plating resist layer 32 in the same manner. Then, the first plating resist layer 31 and the second plating resist layer 32 are removed.

Thus, the lead frame 1a according to the second embodiment is obtained, as shown in FIG. 18.

Refer to a partial enlarged sectional view and a partial enlarged plan view of FIG. 18 additionally. In the second embodiment, as a second example of a structure in which a circumferential edge portion of a lower surface of the first metal plating layer 40 makes contact with a first protruding portion E1, an area of the first metal plating layer 40 is set to be smaller than an area of the upper surface of the electrode 14a. The first metal plating layer 40 is disposed to cover the central portion of the upper surface of the electrode 14a, and the circumferential edge portion of the upper surface of the electrode 14a is exposed from the first metal plating layer 40.

Also refer to the aforementioned structure of the first metal plating layer 40 shown in FIG. 12 in the first embodiment. The area of the first metal plating layer 40 is set to be equal to or smaller than the area of the upper surface of the electrode 14a.

Steps the same as the aforementioned steps of FIGS. 13A and 13B, FIGS. 14A and 14B and FIG. 15 are executed on the lead frame 1a shown in FIG. 8 Thus, the electronic component device 2a according to the second embodiment is obtained, as shown in FIG. 19.

The lead frame 1a and the electronic component device 2a according to the second embodiment can obtain the same effects as those according to the first embodiment.

Further, in the terminal portion 14 of the lead frame 1a of the electronic component device 2a according to the second embodiment, the circumferential edge portion of the upper surface of the electrode 14a is exposed from the first metal plating layer 40. Thus, a contact area between the electrode 14a and the sealing resin 60 is increased.

A metal plate 10 which forms the electrode 14a has higher adhesion to the sealing resin 60 than the first metal plating layer 40. Accordingly, adhesion between the electrode 14a and the sealing resin 60 is improved. Therefore, a structure in which the terminal portion 14 can be prevented from being detached from the sealing resin 60 easily is obtained.

### Third Embodiment

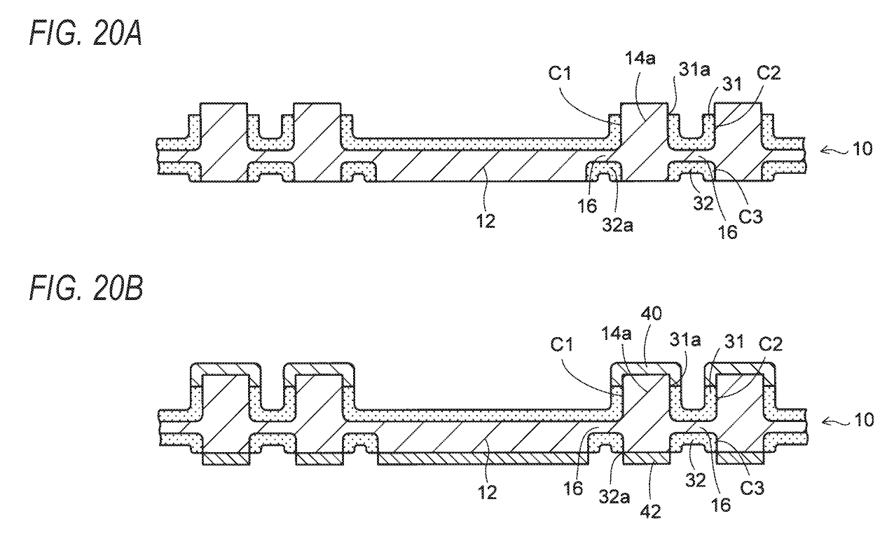

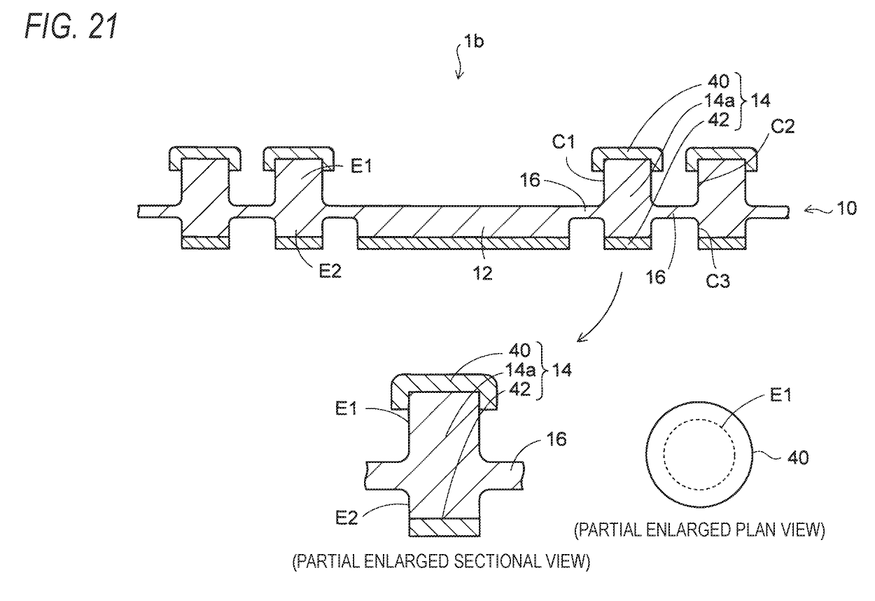

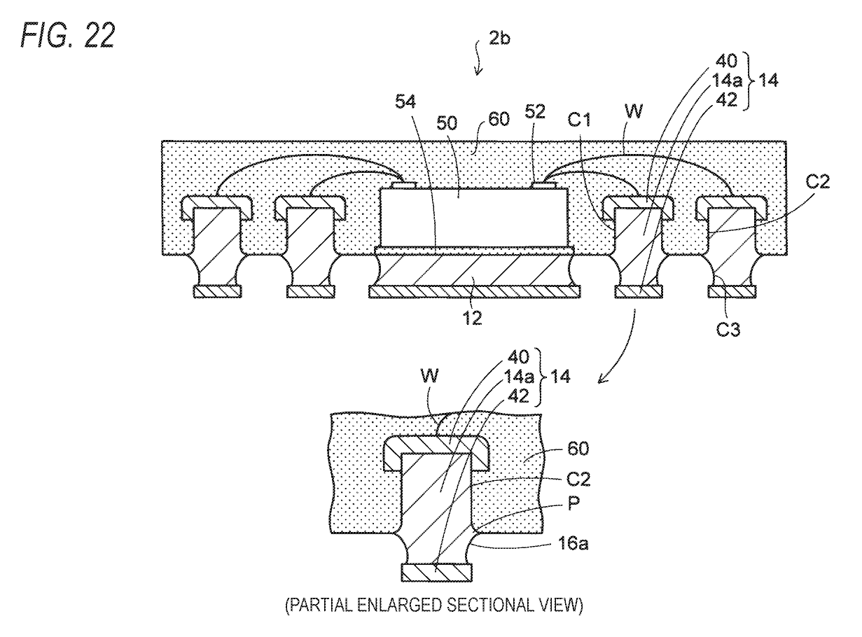

FIGS. 20A and 20B and FIG. 21 are views for explaining a lead frame according to a third embodiment. FIG. 22 is a view showing an electronic component device according to the third embodiment.

In a manufacturing method for the lead frame according to the third embodiment, positions of opening portions 31a of a first plating resist layer 31 in the aforementioned step of FIGS. 10A and 10B are changed, as shown in FIG. 20A. In the third embodiment, the first plating resist layer 31 is patterned so that upper surfaces and side surface upper portions of electrodes 14a can be exposed from the opening portions 31a of the first plating resist layer 31.

Next, as shown in FIG. 20B, a first metal plating layer 40 is formed on the upper surfaces and the side surface upper portions of the electrodes 14a inside the opening portions 31a of the first resist layer 31 in the same manner as in the aforementioned step of FIG. 11. In addition, a second metal plating layer 42 is formed on lower surfaces of the electrodes 14a inside opening portions 32a of a second plating resist layer 32 in the same manner. Then, the first plating resist layer 31 and the second plating resist layer 32 are removed.

Thus, the lead frame 1b according to the third embodiment is obtained, as shown in FIG. 21.

Refer to a partial enlarged sectional view and a partial enlarged plan view in FIG. 21. In the third embodiment, as a third example of a structure in which a circumferential edge portion of a lower surface of the first metal plating layer 40 makes contact with a first protruding portion E1, the first metal plating layer 40 is formed to extend from the upper surface of the electrode 14a to the side surface of the electrode 14a. A side surface lower portion of the first protruding portion E1 of a terminal portion 14 is exposed from the first metal plating layer 40.

The same steps as the aforementioned steps of FIGS. 13A and 13B, FIGS. 14A and 14B and FIG. 15 are performed on the lead frame 1b shown in FIG. 21. Thus, the electronic component device 2b according to the third embodiment is obtained, as shown in FIG. 22.

The lead frame 1b and the electronic component device 2b according to the third embodiment can obtain the same effects as those according to the first embodiment.

Further, in the terminal portion 14 of the lead frame 1b of the electronic component device 2b according to the third embodiment, the first metal plating layer 40 is formed to extend from the upper surface of the electrode 14a to the side surface of the electrode 14a. Thus, adhesion between the first metal plating layer 40 and the electrode 14a can be improved so that the first metal plating layer 40 can be further prevented from being detached.

### Fourth Embodiment

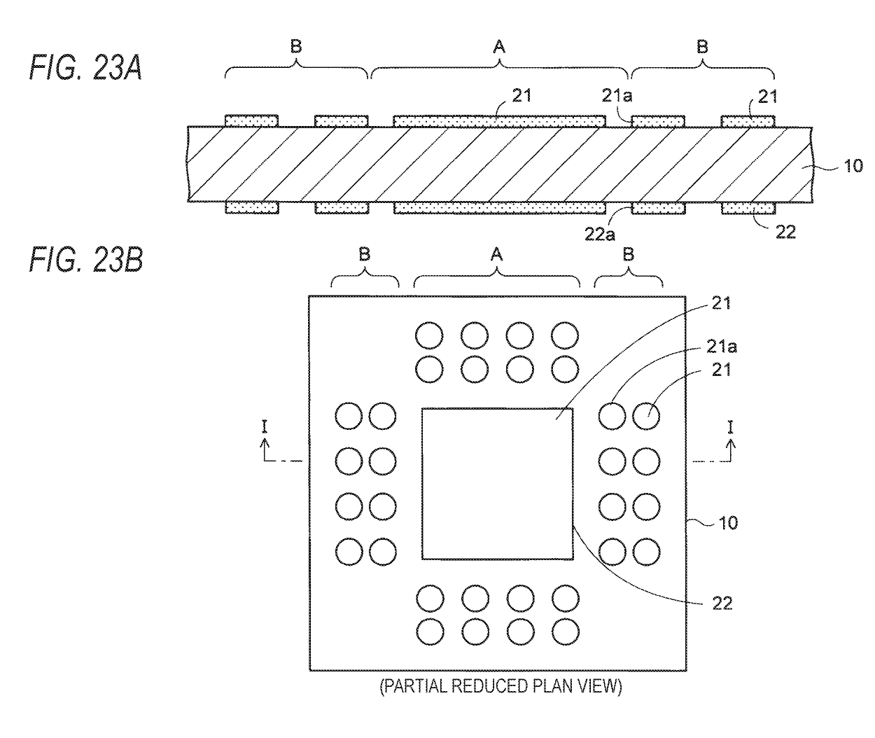

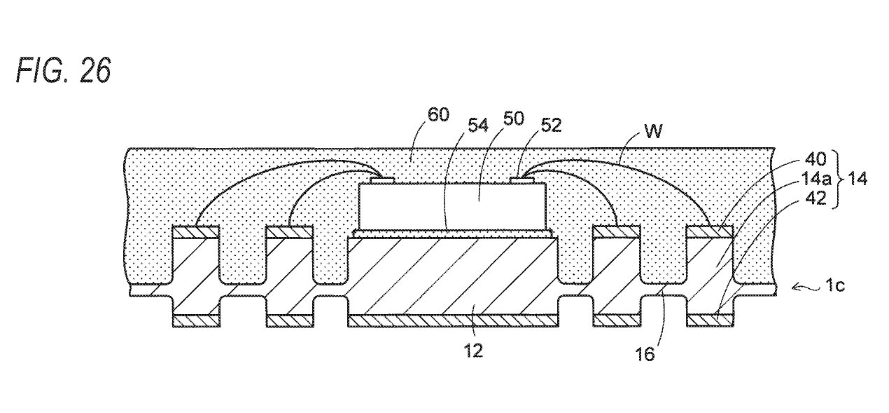

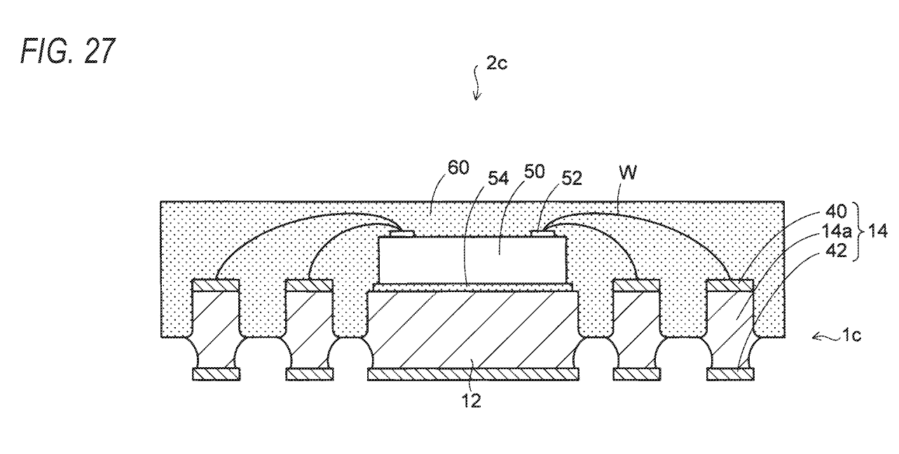

FIGS. 23A and 23B, FIGS. 24A and 24B and FIG. 25 are views for explaining a lead frame according to a fourth embodiment. FIG. 26 and FIG. 27 are views showing an electronic component device according to the fourth embodiment.

In the fourth embodiment, a die pad portion of the lead frame is formed to protrude from a lower surface and an upper surface of a metal plate.

In the fourth embodiment, patterns of a first resist layer 21 are also disposed on a die pad formation region A of the upper surface of the metal plate 10 in the aforementioned step of FIGS. 6A and 6B, as shown in FIGS. 23A and 23B.

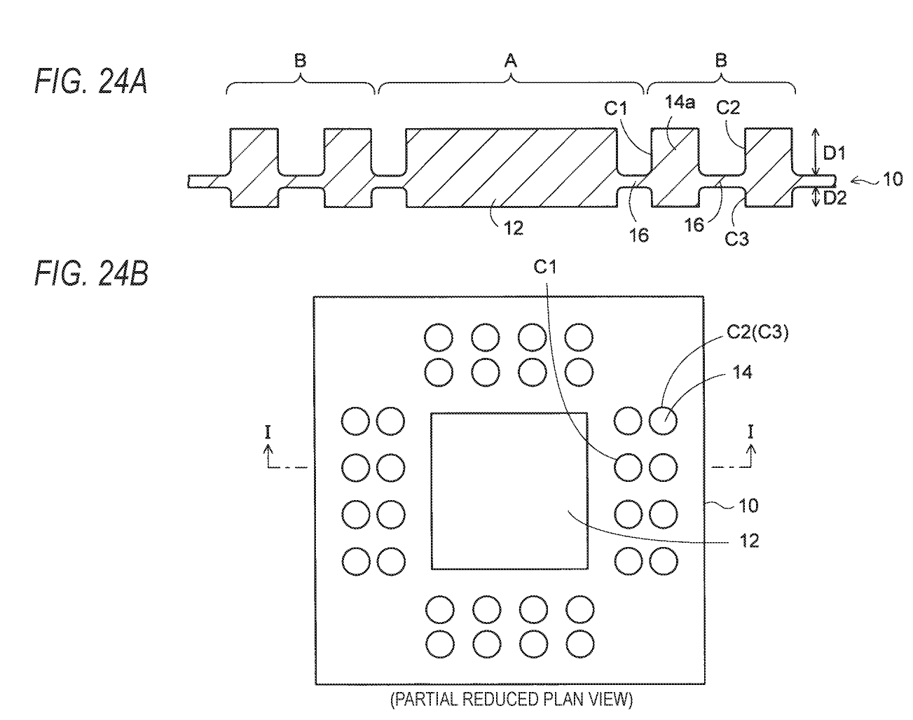

Next, using the first resist layer 21 and a second resist layer 22 as masks, the metal plate 10 is wet-etched to the middle of its thickness from its opposite surface sides by the same method as in the aforementioned step of FIG. 7A, as shown in FIGS. 24A and 24B.

FIGS. 24A and 24B show a state after the first resist layer 21 and the second resist layer 22 have been removed.

In the fourth embodiment, the die pad portion 12 is formed to protrude from a lower surface and an upper surface of a coupling portion 16 of the metal plate 10, as shown in FIGS. 24A and 24B.

Successively, the same steps as the aforementioned steps of FIGS. 10A to 12 are performed on a structure body shown in FIG. 24A.

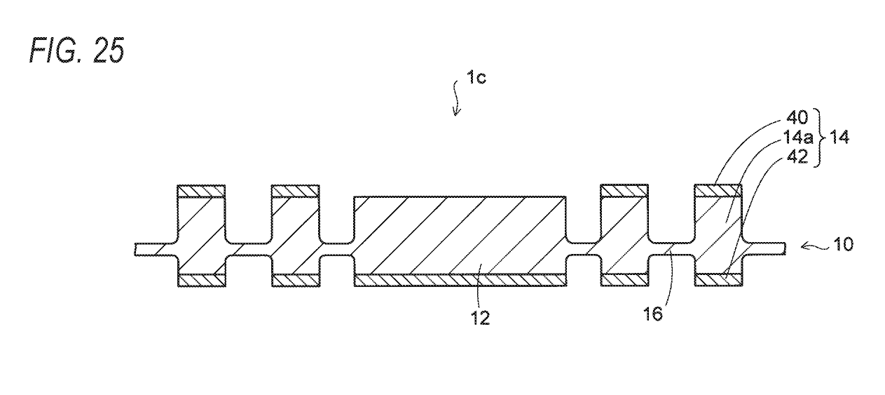

Thus, the lead frame 1c according to the fourth embodiment is obtained, as shown in FIG. 25. The lead frame 1c according to the fourth embodiment is different from the lead frame 1 according to the first embodiment in that the die pad portion 12 protrudes from the upper surface of the metal plate 10. A height position of an upper surface of the die pad portion 12 is the same as a height position of an upper surface of an electrode 14a of each terminal portion 14.

The other elements are the same as those in the lead frame 1 according to the first embodiment.

Next, as shown in FIG. 26, a semiconductor chip 50 is fixed on the die pad portion 12 of the lead frame 1c in FIG. 25 by an adhesive agent 54 in the same manner as in the aforementioned step of FIG. 13A. Next, connection terminals 52 of the semiconductor chip 50 are connected to a first metal plating layer 40 of the terminal portions 14 of the lead frame 1c through wires W in the same manner as in the aforementioned step of FIG. 14A.

Successively, a sealing resin 60 for sealing the semiconductor chip 50, the terminal portions 14 and the wires W is formed on the lead frame 1c in the same manner as in the aforementioned step of FIG. 14B.

Further, using a second metal plating layer 42 in lower surfaces of the terminal portions 14 as a mask, the coupling portion 16 of the lead frame 1c is wet-etched from its lower surface side in the same manner as in the aforementioned step of FIGS. 14B and 15, as shown in FIG. 27.

Thus, the die pad portion 12 is separated from the terminal portions 14, and the terminal portions 14 are separated individually.

Then, the sealing resin 60 and the lead frame 1c are cut so that each individual product can be obtained.

In the aforementioned manner, the electronic component device 2c according to the fourth embodiment is obtained, as shown in FIG. 27.

The lead frame 1c and the electronic component device 2c according to the fourth embodiment can obtain the same effects as those according to the first embodiment.

Further, in the lead frame 1c according to the fourth embodiment, the die pad portion 12 is formed with the same thickness as the metal plate 10 which has not been machined, as shown in FIG. 27. Therefore, the volume of the die pad portion 12 according to the fourth embodiment is larger than the volume of the die pad portion 12 according to the first embodiment.

The die pad portion 12 is formed of a copper plate high in thermal conductivity. Accordingly, heat generated from the semiconductor chip 50 can dissipate heat from the die pad portion 12 to the outside efficiently. Accordingly, heat dissipation of the electronic component device can be improved.

### Fifth Embodiment

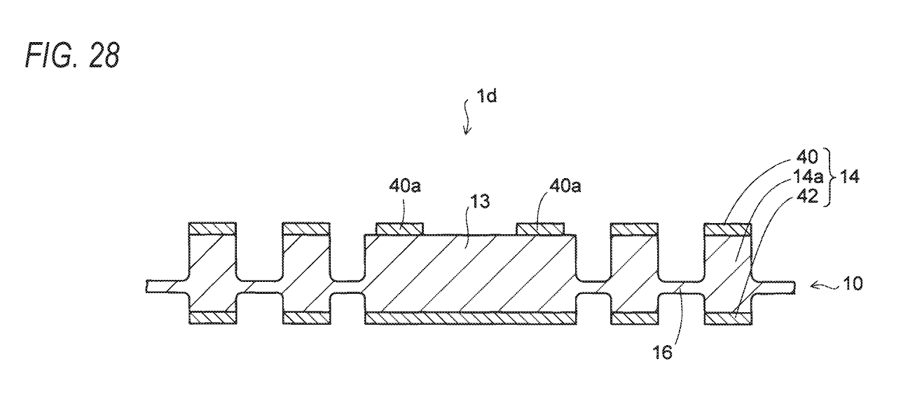

FIGS. 28 to 30 are views for explaining a lead frame and an electronic component device according to a fifth embodiment. In the fifth embodiment, a semiconductor chip is flip-chip connected to the lead frame.

The die pad portion 12 when the aforementioned lead frame 1c of FIG. 25 according to the fourth embodiment is manufactured is formed as a common terminal portion 13 in the fifth embodiment, as shown in FIG. 28.

A plurality of connection electrodes 40a made of the same layer as a first metal plating layer 40 are formed on an upper surface of the common terminal portion 13. In a step of forming the first metal plating layer 40 on upper surfaces of electrodes 14a, the connection electrodes 40a are formed on the upper surface of the common terminal portion 13 simultaneously.

Thus, the lead frame 1d according to the fifth embodiment is obtained, as shown in FIG. 28. The aforementioned die pad portion 12 of the lead frame 1c of FIG. 25 according to the fourth embodiment serves as the common terminal portion 13 in the fifth embodiment, as shown in FIG. 28. The connection electrodes 40a made of the same layer as the first metal plating layer 40 are formed on the upper surface of the common terminal portion 13.

In the fifth embodiment, the connection electrodes 40a on the common terminal portion 13 are formed in the same manner as terminal portions 14 in order to flip-chip connect a semiconductor chip. For example, each of the connection electrodes 40a is formed into a circular pad shape in plan view.

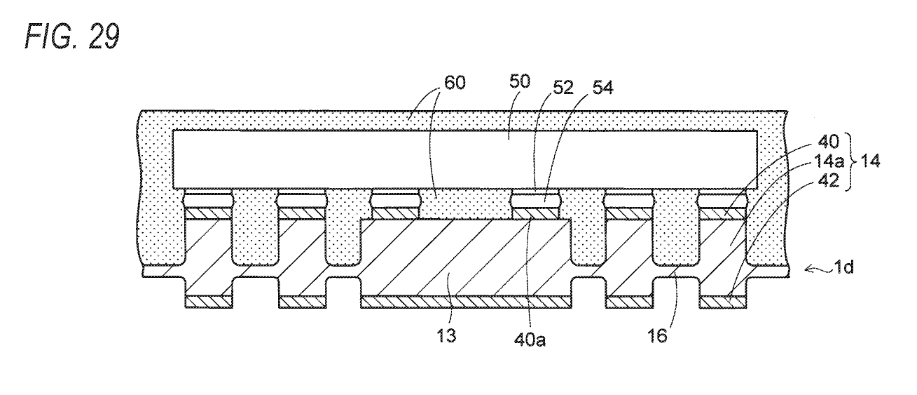

Next, as shown in FIG. 29, a semiconductor chip 50 provided with connection terminals 52 is prepared. Arrangement of the terminal portions 14 and the connection electrodes 40a of the lead frame 1d corresponds to the connection terminals 52 of the semiconductor chip 50.

The connection terminals 52 of the semiconductor chip 50 are flip-chip connected to both the first metal plating layer 40 at upper ends of the terminal portions 14 and the connection electrodes 40a on the common terminal portion 13 through bonding portions 54 such as solder bumps.

Various methods can be used as the bonding method for the semiconductor chip 50. In addition to the solder bumps, gold bumps may be used as the bonding portions 54.

In addition, copper pillars may be formed on the connection terminals 52 of the semiconductor chip 50 and bonded to the terminal portions 14 and the connection electrodes 40a by soldering.

Then, a gap between the semiconductor chip 50 and the lead frame 1d is filled with a sealing resin 60, and an upper surface and a side surface of the semiconductor chip 50 are sealed with the sealing resin 60, as shown in FIG. 9.

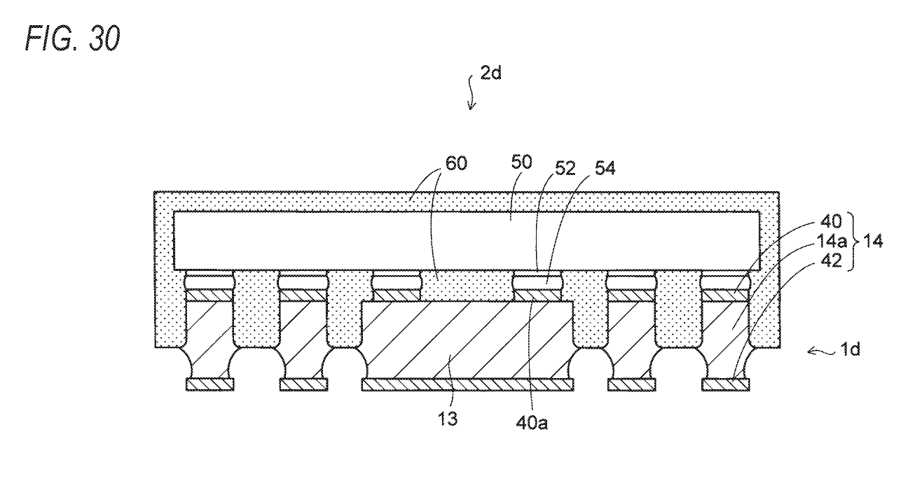

Further, as shown in FIG. 30, using a second metal plating layer 42 in lower surfaces of the terminal portions 14 as a mask, a coupling portion 16 of the lead frame 1d is wet-etched from its lower surface side in the same manner as in the aforementioned step of FIGS. 14B and 15.

Thus, the common terminal portion 13 is separated from the terminal portions 14, and the terminal portions 14 are separated individually.

Then, the sealing resin 60 and the lead frame id are cut so that each individual product can be obtained.

In the aforementioned manner, the electronic component device 2d according to the fifth embodiment is obtained.

In the fifth embodiment, similarly to the terminal portions 14, a lower end and a portion of a side surface of the common terminal portion 13 protrude from the sealing resin 60, and the second metal plating layer 42 under the common terminal portion 13 is exposed from the sealing resin 60.

The lead frame 1d and the electronic component device 2d according to the fifth embodiment can obtain the same effects as those according to the first embodiment.

Further, in the fifth embodiment, the semiconductor chip can be mounted in the flip-chip connection manner. Accordingly, the lead frame Id can be adapted to an increase in the number of terminals of the semiconductor chip.

In addition, the common terminal portion 13 of the lead frame 1d can be used as a common power supply terminal or a common ground terminal corresponding to the connection terminals of the semiconductor chip. Therefore, the lead frame 1d can be adapted to a further increase in the number of terminals of the semiconductor chip.

### Sixth Embodiment

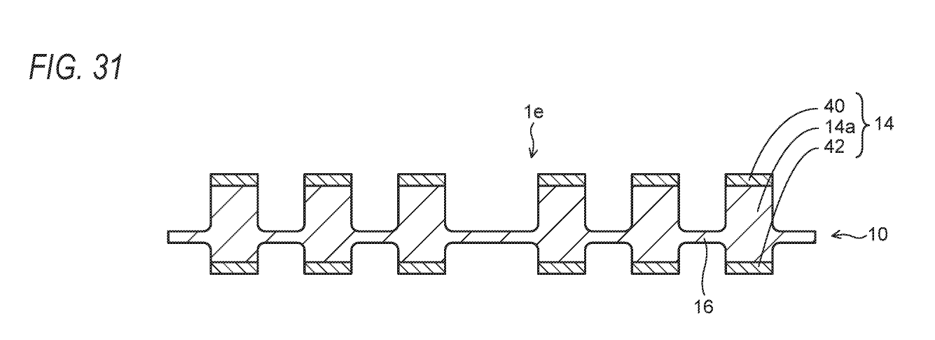

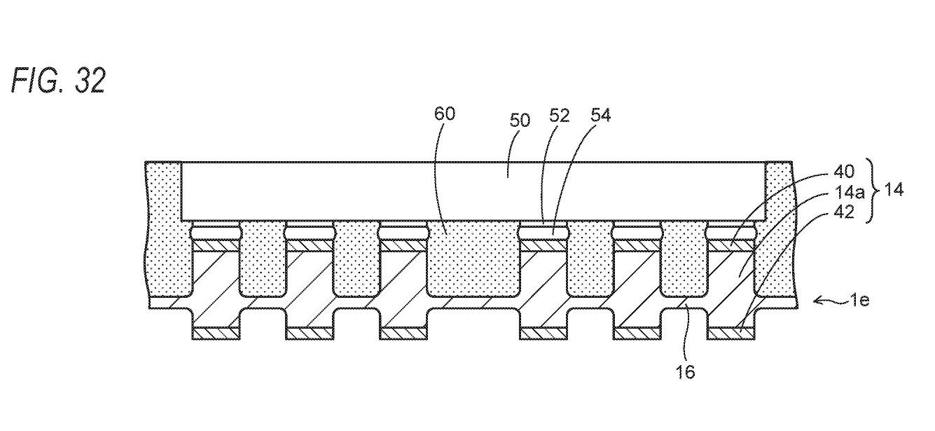

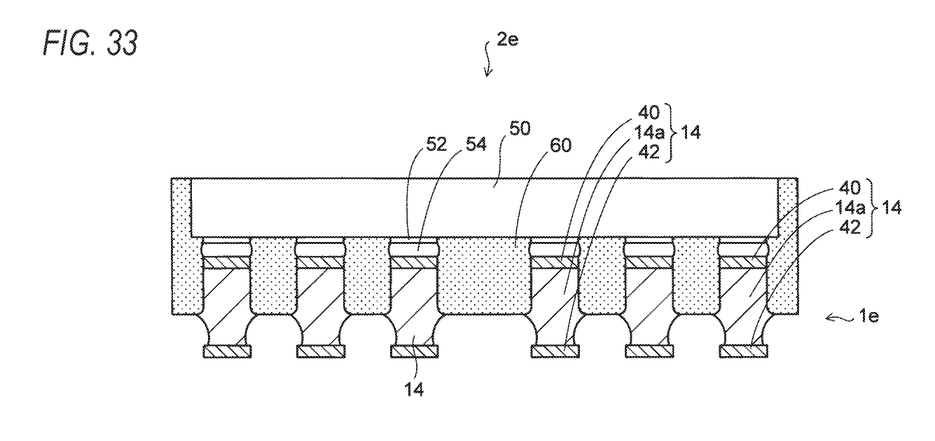

A lead frame 1e and an electronic component device 2e according to a sixth embodiment will be described below with reference to FIGS. 31 to 33. FIG. 31 is a sectional view showing the lead frame 1e according to the sixth embodiment. FIG. 32 is a sectional view showing a manufacturing method for the electronic component device 2e according to the sixth embodiment. FIG. 33 is a sectional view showing the electronic component device 2e according to the sixth embodiment.

As shown in FIG. 31, the lead frame 1e according to the sixth embodiment has a plurality of terminal portions 14 which are separately disposed in a lattice pattern in place of the common terminal portion 13 in the aforementioned lead frame 1d of FIG. 28 according to the fifth embodiment.

Connection terminals 52 of a semiconductor chip 50 are flip-chip connected to a first metal plating layer 40 at upper ends of the terminal portions 14 through bonding portions 54 such as solder bumps. Further, a lower surface and a side surface of the semiconductor chip 50 and the first metal plating layer 40 and upper portions of electrodes 14a in the terminal portions 14 are sealed with a sealing resin 60.

A lower end and a portion of a side surface of the electrode 14a in each of the terminal portions 14 protrude from the sealing resin 60, and a second metal plating layer 42 is exposed from the sealing resin 60.

In the example of FIG. 32, a back surface of the semiconductor chip 50 is exposed from the sealing resin 60. However, the back surface of the semiconductor chip 50 may be sealed with the sealing resin 60.

The electronic component device 2e according to the sixth embodiment in FIG. 33 is the same as the electronic component device 2d according to the fifth embodiment in FIG. 30, except that the terminal portions 14 are disposed in place of the common terminal portion 13.

The electronic component device 2e according to the sixth embodiment is manufactured by the same method as the manufacturing method for the electronic component device 2d according to the fifth embodiment in FIG. 30.

The lead frame 1e and the electronic component device 2e according to the sixth embodiment can obtain the same effects as those according to the first embodiment.

As described above, the exemplary embodiment and the modification are described in detail. However, the present invention is not limited to the above-described embodiment and the modification, and various modifications and replacements are applied to the above-described embodiment and the modifications without departing from the scope of claims.

Various aspects of the subject matter described herein are set out non-exhaustively in the following numbered clauses:

1) A method of manufacturing a lead frame, the method comprising:

a) preparing a metal plate;

b) machining the metal plate to form a columnar electrode;

c) forming a first metal plating layer on an upper surface of the electrode; and

d) forming a second metal plating layer on a lower surface of the electrode.

2) The method according to clause (1), wherein

an area of the first metal plating layer is smaller than an area of the upper surface of the electrode in top view.

3) The method according to clause (1), wherein

the first metal plating layer is formed on the upper surface of the electrode and a portion of a side surface of the electrode in the step c).

4) The method according to clause (1), wherein

step b) includes forming a die pad portion,

the electrode comprises a plurality of electrodes, and

the plurality of electrodes are disposed to surround the die pad portion.

5) A method of manufacturing an electronic component device, the method comprising:

a) forming a lead frame comprising a terminal portion, the terminal portion comprising a columnar electrode, a first metal plating layer formed on an upper surface of the electrode, and a second metal plating layer formed on a lower surface of the electrode:

b) mounting an electronic component on the lead frame to be electrically connected to the terminal portion;

c) sealing a portion of the lead frame and the electronic component with a sealing resin; and

d) etching a portion of the lead frame using the second metal plating layer as a mask.

What is claimed is:

1. A lead frame comprising a terminal portion, the terminal portion comprising:
a columnar electrode;
a first metal plating layer formed on an upper surface of the electrode; and
a second metal plating layer formed on a lower surface of the electrode.

2. The lead frame according to claim 1, wherein
the terminal portion comprises a plurality of terminal portions,
the lead frame further comprises a coupling portion that is coupled to the plurality of terminal portions,
a first distance between the upper surface of the electrode and the coupling portion is larger than a second distance between the lower surface of the electrode and the coupling portion.

3. The lead frame according to claim 2, wherein
a ratio of the first distance to the second distance is in a range of 4.5 to 9.

4. The lead frame according claim 2, wherein
a thickness of the coupling portion is in a range of 10 μm to 20 μm.

5. The lead frame according to claim 1, wherein
an area of the first metal plating layer is smaller than an area of the upper surface of the electrode in top view.

6. The lead frame according to claim 1, wherein
an entire lower surface of the first metal plating layer contacts the upper surface of the electrode.

7. The lead frame according to claim 1, wherein
the first metal plating layer is formed on the upper surface of the electrode and a portion of a side surface of the electrode.

8. The lead frame according to claim 1, further comprising: a die pad portion,
wherein the terminal portion comprises a plurality of terminal portions, and the plurality of terminal portions are disposed to surround the die pad portion.

9. An electronic component device comprising
a lead frame comprising a terminal portion, the terminal portion comprising:
a columnar electrode comprising an upper surface, a lower surface, a side surface between the upper surface and the lower surface, and a protrusion formed on the side surface;
a first metal plating layer formed on the upper surface of the electrode; and
a second metal plating layer formed on the lower surface of the electrode,
an electronic component that is mounted on the lead frame to be electrically connected to the terminal portion;
a sealing resin that seals a portion of the lead frame and the electronic component,
wherein the first metal plating layer and a portion of the side surface of the electrode are embedded in the sealing resin, and the second metal plating layer and another portion of the side surface of the electrode are exposed from the sealing resin.
